(19) United States
(12) Patent Application Publication
(10) Pub. No.: US 2016/0254428 A1
(43) Pub. Date: Sep. 1, 2016

(54) LIGHT EMITTING DEVICE AND FABRICATING METHOD THEREOF

(71) Applicant: Genesis Photonics Inc., Tainan City (TW)

(72) Inventors: Shao-Ying Ting, Tainan City (TW); Jing-En Huang, Tainan City (TW); Yi-Ru Huang, Tainan City (TW); Kuan-Chieh Huang, New Taipei City (TW)

(21) Appl. No.: 15/046,407

(22) Filed: Feb. 17, 2016

Related U.S. Application Data
(63) Continuation-in-part of application No. 14/705,977, filed on May 7, 2015.
(60) Provisional application No. 62/116,923, filed on Feb. 17, 2015.

(30) Foreign Application Priority Data
May 7, 2014 (TW) 103116262
May 14, 2014 (TW) 103116987
Apr. 27, 2015 (TW) 104113482

(51) Int. Cl. H01L 33/62; H01L 33/00; H01L 33/38; H01L 33/52

(52) U.S. Cl. CPC H01L 33/62; H01L 33/52; H01L 33/0079; H01L 33/387; H01L 2933/0066; H01L 2933/005

(57) ABSTRACT

A light emitting device including a circuit board, a light emitting unit, and an anisotropic conductive layer is provided. The circuit board includes a plurality of electrode pads. The light emitting unit includes a semiconductor epitaxial structure layer, a first electrode, and a second electrode. The first electrode and the second electrode are respectively disposed on the same side of the semiconductor epitaxial structure layer. The first electrode and the second electrode are electrically connected to the electrode pads through the anisotropic conductive layer. A fabricating method of a light emitting device is also provided.

### CROSS-REFERENCE TO RELATED APPLICATION

This application is a continuation-in-part application of and claims the priority benefit of a prior application Ser. No. 14/705,977, filed on May 7, 2015, now pending, which claims the priority benefit of Taiwan application serial no. 103116262, filed on May 7, 2014, Taiwan application serial no. 104113482, filed on Apr. 27, 2015, and Taiwan application serial no. 103116987, filed on May 14, 2014. This application also claims the priority benefits of U.S. provisional application Ser. No. 62/116,923, filed on Feb. 17, 2015. The entirety of each of the above-mentioned patent applications is hereby incorporated by reference herein and made a part of this specification.

### BACKGROUND OF THE INVENTION

1. Field of the Invention

The invention relates to a light emitting device and a fabricating method thereof.

2. Description of Related Art

In the structure of a conventional flip-chip light emitting diode package, an edge of a semiconductor epitaxial structure layer may be aligned with or retracted from an edge of the substrate, and edges of an N electrode and a P electrode may be aligned with the edge of the semiconductor epitaxial structure layer or spaced from the edge of the semiconductor epitaxial structure layer in a vertical distance. In other words, areas of orthogonal projections of the N electrode and the P electrode on the substrate are smaller than an area of an orthogonal projection of the semiconductor epitaxial structure layer on the substrate. In such arrangement, when a flip-chip light emitting diode package is to be assembled to an external circuit, the alignment may not be sufficiently precise and the contact of electrodes may be poor when the light emitting diode package is assembled, because the electrode areas of the N electrode and the P electrode are relatively smaller.

Also, according to the conventional method of assembling a flip-chip light emitting diode, a light emitting diode epitaxial thin film may be directly assembled to the external circuit, in addition to assembling the light emitting diode package to the external circuit. Generally speaking, the light emitting diode package or the light emitting diode epitaxial thin film may be directly bonded to the external circuit or bonded to the external circuit through a solder. However, during the soldering process, the solder is heated and becomes flowable, which easily results in a short circuit in a horizontal direction in the assembled light emitting device. In addition, when a subsequent process is performed on the light emitting device assembled by using the conventional bonding process and material, the stress generated in the subsequent process may result in damages or current leakage in the light emitting device, making the yield rate of the light emitting device lower.

### SUMMARY OF THE INVENTION

The invention provides a light emitting device that does not easily have a short circuit or current leakage in a horizontal direction and consequently has a preferable yield rate.

The invention provides a fabricating method of a light emitting device. The light emitting device manufactured accordingly does not easily have a short circuit or current leakage in a horizontal direction and consequently has a preferable yield rate.

A light emitting device according to an embodiment of the invention includes a circuit board, a light emitting unit, and an anisotropic conductive layer. The circuit board includes a plurality of electrode pads. The light emitting unit includes a semiconductor epitaxial structure layer, a first electrode, and a second electrode. The first electrode and the second electrode are respectively disposed on the same side of the semiconductor epitaxial structure layer. The first electrode and the second electrode are electrically connected to the electrode pads through the anisotropic conductive layer.

According to an embodiment of the invention, the light emitting unit further includes a substrate. The semiconductor epitaxial layer is disposed on the substrate, and the first electrode and the second electrode are disposed on a side of the semiconductor epitaxial structure layer away from the substrate.

According to an embodiment of the invention, the light emitting device further includes a light transmissive layer. The light emitting unit is disposed on the light transmissive layer, the light emitting unit is disposed between the light transmissive layer and the first electrode and between the light transmissive layer and the second electrode.

According to an embodiment of the invention, the light emitting device further includes an encapsulant. The encapsulant encapsulates the light emitting unit, and exposes at least a part of the first electrode and a part of the second electrode.

According to an embodiment of the invention, the anisotropic conductive layer includes an insulating paste and a plurality of conductors distributed in the insulating paste.

A fabricating method of a light emitting device according to an embodiment of the invention includes steps as follows. First of all, a circuit board including a plurality of electrode pads is provided. A light emitting unit is provided. The light emitting unit includes a semiconductor epitaxial structure layer and a first electrode and a second electrode disposed on the semiconductor epitaxial structure layer. An anisotropic conductive layer is attached to the circuit board or the light emitting unit. The first electrode and the second electrode are aligned with the electrode pads. A process is performed on the anisotropic conductive layer, such that the first electrode and the second electrode are electrically connected with the electrode pads.

According to an embodiment of the invention, the process includes pressing parts of the anisotropic conductive layer corresponding to the first electrode and the second electrode, such that the parts of the anisotropic conductive layer corresponding to the first electrode and the second electrode are respectively electrically connected with the first electrode and the second electrode.

According to an embodiment of the invention, the process includes heating parts of the anisotropic conductive layer corresponding to the first electrode and the second electrode, such that the parts of the anisotropic conductive layer corresponding to the first electrode and the second electrode are respectively electrically connected with the first electrode and the second electrode.

According to an embodiment of the invention, the light emitting unit further includes a substrate. A semiconductor epitaxial structure layer is disposed on the substrate. The fabricating method of the light emitting device further includes removing the substrate after electrically connecting the first electrode and the second electrode with the electrode pads.

According to an embodiment of the invention, process of removing the substrate includes removing the substrate by performing a laser lift-off process.

According to an embodiment of the invention, the anisotropic conductive layer includes an insulating paste and a plurality of conductors distributed in the insulating paste.

A light emitting device according to an embodiment of the invention includes a circuit board, a light emitting unit, a light transmissive layer, an encapsulant, and an anisotropic conductive layer. The light emitting unit includes a substrate, a semiconductor epitaxial structure layer disposed on the substrate, a first electrode, and a second electrode. The first electrode and the second electrode are respectively disposed on the same side of the semiconductor epitaxial structure layer. The light emitting unit is disposed on the light transmissive layer and the light transmissive layer at least exposes the first electrode and the second electrode. The encapsulant encapsulates the light emitting unit and at least exposes a part of the first electrode and a part of the second electrode. The first electrode and the second electrode respectively extend outward from the semiconductor epitaxial structure layer, and respectively cover at least a part of an upper surface of the encapsulant. The first electrode and the second electrode are electrically connected to the circuit board through the anisotropic conductive layer.

According to an embodiment of the invention, the anisotropic conductive layer includes an insulating paste and a plurality of conductors distributed in the insulating paste.

According to an embodiment of the invention, the first electrode includes a first electrode portion connected to the semiconductor epitaxial structure layer and a first electrode extending portion connected to the first electrode portion, and the second electrode includes a second electrode portion connected to the semiconductor epitaxial structure layer and a second electrode extending portion connected to the second electrode portion, and the first electrode extending portion and the second electrode extending portion respectively extend outward to at least a part of the upper surface of the encapsulant.

According to an embodiment of the invention, the first electrode extending portion and the second electrode extending portion are aligned with or retracted from an edge of the upper surface of the encapsulant.

According to an embodiment of the invention, the first electrode portion and the second electrode portion are aligned with or retracted from an edge of the semiconductor epitaxial structure layer.

According to an embodiment of the invention, the light emitting device further includes one or a plurality of flat surfaces, and each of the flat surfaces includes the light transmissive layer and the encapsulant.

According to an embodiment of the invention, the first electrode extending portion includes a plurality of first grating type electrodes, and the second electrode extending portion includes a plurality of second grating type electrodes, the first grating type electrodes are distributed on the first electrode portion and a part of the upper surface of the encapsulant, and the second grating type electrodes are distributed on the second electrode portion and a part of the upper surface of the encapsulant.

According to an embodiment of the invention, at least a part of the first electrode extending portion extends from an edge of the first electrode portion towards a direction away from the second electrode portion, and at least a part of the second electrode extending portion extends from an edge of the second electrode portion towards a direction away from the first electrode portion.

According to an embodiment of the invention, the first electrode extending portion and the second electrode extending portion respectively include a plurality of sub-electrodes separated from each other.

According to an embodiment of the invention, the first sub-electrodes of the first electrode extending portion are located in at least one corner away from the second electrode on the upper surface of the encapsulant, and the second sub-electrodes of the second electrode extending portion are located in at least one corner away from the first electrode on the upper surface of the encapsulant.

According to an embodiment of the invention, top surfaces of the first electrode extending portion and the second electrode extending portion are substantially coplanar with the upper surface of the encapsulant.

According to an embodiment of the invention, the first electrode portion and the first electrode extending portion are seamlessly connected, and the second electrode portion and the second electrode extending portion are seamlessly connected.

According to an embodiment of the invention, the first electrode extending portion and the second electrode extending portion respectively include an adhesion layer and a barrier layer disposed between the adhesion layer and the encapsulant.

According to an embodiment of the invention, a material of the adhesion layer includes gold, tin, aluminium, silver, copper, indium, bismuth, platinum, gold-tin alloy, tin-silver alloy, tin-silver-copper alloy (Sn—Ag—Cu (SAC) alloy) or a combination thereof, and a material of the barrier layer includes nickel, titanium, tungsten, gold or an alloy of a combination thereof.

According to an embodiment of the invention, the first electrode and the second electrode respectively include a reflection layer respectively disposed between the electrode extending portions and the encapsulant.

According to an embodiment of the invention, a material of the reflection layer includes gold, aluminium, silver, nickel, titanium or an alloy of a combination thereof.

According to an embodiment of the invention, the light emitting device further includes a reflection layer disposed on a surface of the encapsulant.

According to an embodiment of the invention, at least a part of the reflection layer is located between the electrodes and the encapsulant.

According to an embodiment of the invention, a material of the reflection layer includes gold, aluminium, silver, nickel, titanium, distributed Bragg reflector (DBR), a resin layer doped with reflection particles with high reflectivity or a combination thereof.

According to an embodiment of the invention, the light emitting device further includes a wavelength conversion material wrapping the light emitting unit and at least exposing a part of the first electrode and a part of the second electrode.

According to an embodiment of the invention, the wavelength conversion material includes a fluorescent material or a quantum dot material.

According to an embodiment of the invention, the wavelength conversion material is formed on a surface of the light emitting unit, formed on a surface of the encapsulant or mixed in the encapsulant.

According to an embodiment of the invention, the first sub-electrodes and the second sub-electrodes are laminar electrodes, spherical electrodes, or grating type electrodes.

A light emitting device according to an embodiment of the invention includes a circuit board, a light emitting unit, a light transmissive layer, an encapsulant, and an anisotropic conductive layer. The light emitting unit includes a substrate, a semiconductor epitaxial structure layer disposed on the substrate, a first electrode, and a second electrode. The first electrode and the second electrode are respectively disposed on the same side of the semiconductor epitaxial structure layer opposite to the substrate. The light transmissive layer is disposed on the light emitting unit and located at a side of the substrate opposite to the semiconductor epitaxial structure layer, the first electrode and the second electrode. The encapsulant is located between the light emitting unit and the light transmissive unit. The encapsulant encapsulates the light emitting unit, and exposes at least a part of the first electrode and a part of the second electrode. The first electrode and the second electrode respectively extend outward from the semiconductor epitaxial structure layer, and respectively cover at least a part of an upper surface of the encapsulant. The first electrode and the second electrode are electrically connected to the circuit board through the anisotropic conductive layer.

A light emitting device according to an embodiment of the invention includes a circuit board, a light emitting unit, an encapsulant, and an anisotropic conductive layer. The light emitting unit includes a substrate, a semiconductor epitaxial structure layer disposed on the substrate, a first electrode, and a second electrode. The first electrode and the second electrode are disposed on the same side of the semiconductor epitaxial structure layer. The encapsulant encapsulates the light emitting unit, and exposes at least a part of the first electrode and a part of the second electrode. The first electrode and the second electrode respectively extend upward from the semiconductor epitaxial structure layer without covering an upper surface of the encapsulant. The first electrode and the second electrode are electrically connected to the circuit board through the anisotropic conductive layer.

A light emitting device according to an embodiment of the invention includes a circuit board, a light emitting unit, an encapsulant, and an anisotropic conductive layer. The light emitting unit includes a substrate, a semiconductor epitaxial structure layer disposed on the substrate, a first electrode, and a second electrode. The first electrode and the second electrode are respectively disposed on the same side of the semiconductor epitaxial structure layer. The encapsulant encapsulates the light emitting unit, and exposes at least a part of the first electrode and a part of the second electrode. The first electrode and the second electrode respectively extend outward from the semiconductor epitaxial structure layer without covering an upper surface of the encapsulant. The first electrode and the second electrode are electrically connected to the circuit board through the anisotropic conductive layer.

A light emitting device according to an embodiment of the invention includes a circuit board, a light emitting unit, a light transmissive layer, an encapsulant, and an anisotropic conductive layer. The light emitting unit includes a substrate, a semiconductor epitaxial structure layer disposed on the substrate, a first electrode, and a second electrode. The first electrode and the second electrode are respectively disposed on the same side of the semiconductor epitaxial structure layer. The light emitting unit is disposed on the light transmissive layer and the light transmissive layer at least exposes the first electrode and the second electrode. The encapsulant encapsulates the light emitting unit, and exposes at least a part of the first electrode and a part of the second electrode. The first electrode and the second electrode respectively extend upward from the semiconductor epitaxial structure layer without covering an upper surface of the encapsulant. The first electrode and the second electrode are electrically connected to the circuit board through the anisotropic conductive layer.

A light emitting device according to an embodiment of the invention includes a circuit board, a light emitting unit, a light transmissive layer, an encapsulant, and an anisotropic conductive layer. The light emitting unit includes a substrate, a semiconductor epitaxial structure layer disposed on the substrate, a first electrode, and a second electrode. The first electrode and the second electrode are respectively disposed on the same side of the semiconductor epitaxial structure layer opposite to the substrate. The light transmissive layer is disposed on the light emitting unit and located at a side of the substrate opposite to the semiconductor epitaxial structure layer, the first electrode and the second electrode. The encapsulant is located between the light emitting unit and the light transmissive unit. The encapsulant encapsulates the light emitting unit, and exposes at least a part of the first electrode and a part of the second electrode. The first electrode and the second electrode respectively extend upward from the semiconductor epitaxial structure layer without covering an upper surface of the encapsulant. The first electrode and the second electrode are electrically connected to the circuit board through the anisotropic conductive layer.

Based on above, the first electrode and the second electrode of the light emitting unit according to an embodiment of the invention extend outward from the semiconductor epitaxial structure layer and may cover at least a part of the encapsulant. Namely, when compared with the conventional design of the first electrode and the second electrode, the light emitting device (light emitting diode package) of the invention has a larger electrode area, so that when the light emitting device is to be assembled to an external circuit, the alignment accuracy of assembling is able to be effectively improved. Since the first electrode and the second electrode of the light emitting unit according to the embodiment of the invention extend upward from the semiconductor epitaxial structure layer, and protrude out of the encapsulant, it avails a follow-up chip bonding process. Moreover, in the light emitting device and the fabricating method thereof according to the embodiments of the invention, the first electrode and the second electrode in the light emitting unit of the light emitting device according to the embodiments of the invention are electrically connected to the circuit board through the anisotropic conductive layer. Thus, the light emitting device does not easily have a short circuit or current leakage in the horizontal direction, and the light emitting device has a preferable yield rate.

In order to make the aforementioned and other features and advantages of the invention comprehensible, several exemplary embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a schematic top view of a light emitting device according to an embodiment of the invention.

FIG. 1B is a schematic cross-sectional view along a line A-A of FIG. 1A.

FIG. 2A is a schematic top view of a light emitting device according to another embodiment of the invention.

FIG. 2B is a schematic cross-sectional view along a line B-B of FIG. 2A.

FIG. 3A is a schematic top view of a light emitting device according to another embodiment of the invention.

FIG. 3B is a schematic cross-sectional view along a line C-C of FIG. 3A.

FIG. 4A is a schematic top view of a light emitting device according to another embodiment of the invention.

FIG. 4B is a schematic cross-sectional view along a line D-D of FIG. 4A.

FIG. 5A is a schematic top view of a light emitting device according to another embodiment of the invention.

FIG. 5B is a schematic cross-sectional view along a line E-E of FIG. 5A.

FIG. 6A is a schematic top view of a light emitting device according to another embodiment of the invention.

FIG. 6B is a schematic cross-sectional view along a line F-F of FIG. 6A.

FIG. 7A is a schematic top view of a light emitting device according to another embodiment of the invention.

FIG. 7B is a schematic cross-sectional view along a line G-G of FIG. 7A.

FIG. 8A is a schematic top view of a light emitting device according to another embodiment of the invention.

FIG. 8B is a schematic cross-sectional view along a line H-H of FIG. 8A.

FIG. 9A is a schematic top view of a light emitting device according to another embodiment of the invention.

FIG. 9B is a schematic cross-sectional view along a line I-I of FIG. 9A.

FIG. 10A is a schematic top view of a light emitting device according to another embodiment of the invention.

FIG. 10B is a schematic cross-sectional view along a line J-J of FIG. 10A.

FIG. 11A is a schematic top view of a light emitting device according to another embodiment of the invention.

FIG. 11B is a schematic cross-sectional view along a line K-K of FIG. 11A.

FIG. 12A is a schematic top view of a light emitting device according to another embodiment of the invention.

FIG. 12B is a schematic cross-sectional view illustrating a light emitting device bonded to a circuit board through flip-chip bonding along a line L-L of FIG. 12A.

FIG. 13 is a schematic top view of a light emitting device according to another embodiment of the invention.

FIG. 14 is a schematic cross-sectional view of a light emitting device according to another embodiment of the invention.

FIG. 15A is a schematic top view of a light emitting device according to another embodiment of the invention.

FIG. 15B is a schematic cross-sectional view of the light emitting device of FIG. 15A viewing along a line M-M.

FIG. 16A is a schematic top view of a light emitting device according to another embodiment of the invention.

FIG. 16B is a schematic cross-sectional view of the light emitting device of FIG. 16A viewing along a line N-N.

FIG. 17A is a schematic top view of a light emitting device according to another embodiment of the invention.

FIG. 17B is a schematic cross-sectional view of the light emitting device of FIG. 17A viewing along a line P-P.

FIG. 18A is a schematic cross-sectional view according to an embodiment of the invention where the light emitting device of FIG. 1B is bonded to a circuit board through flip-chip bonding.

FIG. 18B is a partial enlarged view illustrating a region M1 of FIG. 18A.

FIG. 18C is a schematic cross-sectional view according to another embodiment of the invention where the light emitting device of FIG. 1B is bonded to a circuit board through flip-chip bonding.

FIGS. 19A to 19D are schematic views illustrating fabrication of a light emitting device according to an embodiment of the invention.

FIG. 20 is a flowchart illustrating a fabricating method of a light emitting device according to an embodiment of the invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

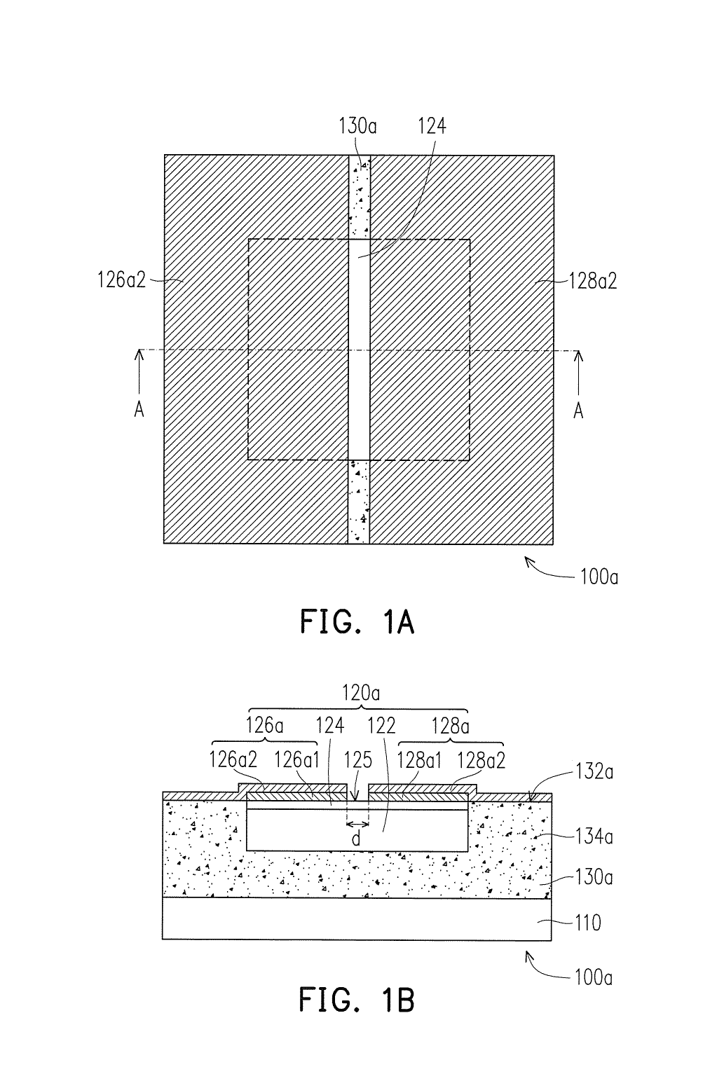

FIG. 1A is a schematic top view of a light emitting device according to an embodiment of the invention. FIG. 1B is a schematic cross-sectional view along a line A-A of FIG. 1A. Referring to FIGS. 1A and 1B together, in this embodiment, a light emitting device 100a includes a light transmissive layer 110, a light emitting unit 120a, and an encapsulant 130a. The light emitting unit 120a is a light emitting diode, for example, and includes a substrate 122, an epitaxial structure layer 124, a first electrode 126, and a second electrode 128a. The epitaxial structure layer 124 is disposed on the substrate 122. In this embodiment, the epitaxial structure layer 124 is a semiconductor epitaxial structure layer. A periphery of the epitaxial structure layer 124 is aligned with a periphery of the substrate 122. The first electrode 126a is disposed on a side of the epitaxial structure layer 124. The second electrode 128a is disposed on the epitaxial structure layer 124, where the second electrode 128a and the first electrode 126a are located on the same side of the epitaxial structure layer 124 opposite to the substrate 122, and the first electrode 126a and the second electrode 128a have an interval d therebetween. The light emitting unit 120a is disposed on the light transmissive layer 110, and the light transmissive layer 110 is located at one side of the substrate 122 of the light emitting unit 120a that is opposite to the epitaxial structure layer 124, the first electrode 126a and the second electrode 128a, and at least exposes a part of the first electrode 126a and a part of the second electrode 128a. The encapsulant 130a is disposed on the light transmissive layer 110, and is located between the light emitting unit 120a and the light transmissive layer 110, where the encapsulant 130a encapsulates the light emitting unit 120a and exposes at least a part of the first electrode 126a and a part of the second electrode 128a, and the first electrode 126a and the second electrode 128a respectively extend outward from the epitaxial structure layer 124, and respectively cover at least a part of an upper surface 132a of the encapsulant 130a. In detail, the epitaxial structure layer 124 at least includes a first semiconductor layer (not shown), a light emitting layer (not shown) and a second semiconductor layer (not shown) electrically connected to each other in a sequence, where the first electrode 126a is electrically connected to the first semiconductor layer, and the second electrode 128a is electrically connected to the second semiconductor layer. In the embodiment, an edge of the encapsulant 130a is aligned with an edge of the light transmissive layer 110, such that the light emitting device 100a has one or a plurality of flat surfaces.

In detail, the light transmissive layer 110 of the embodiment is adapted to guide the light emitted by the light emitting unit 120a and is pervious to the light. A material of the light transmissive layer 110 is, for example, a transparent inorganic material, which includes but is not limited to glass or ceramic; or a transparent organic material, which includes but is not limited to silicone, epoxy resin, or various resins, and a light transmittance of the light transmissive layer 110 is at least 50%, preferably. A pattern of the light transmissive layer 110 can be a flat light transmissive plate or a light transmissive layer with other shapes. In other embodiments of the invention, the light emitting device 100a may not include the light transmissive layer 110, and the encapsulant 130a has one or a plurality of flat surfaces. The light emitting unit 120a is, for example, a flip-chip light emitting diode (LED) chip, where a material of the substrate 122 of the light emitting unit 120a is, for example, sapphire, gallium nitride, gallium oxide, silicon carbide or zinc oxide, though the invention is not limited thereto. Moreover, the first electrode 126a of the embodiment includes a first electrode portion 126a1 and a first electrode extending portion 126a2. The second electrode 128a includes a second electrode portion 128a1 and a second electrode extending portion 128a2. Edges of the first electrode portion 126a1 and the second electrode portion 128a1 are aligned with or not aligned with (for example, retracted from) the edge of the epitaxial structure layer 124. The first electrode extending portion 126a2 is located on the first electrode portion 126a1, and extends outward to cover the upper surface 132a of the encapsulant 130a. The second electrode extending portion 128a2 is located on the second electrode portion 128a1, and extends outward to cover the upper surface 132a of the encapsulant 130a. Here, the first electrode portion 126a1 and the first electrode extending portion 126a2 may adopt the same material or different materials, and the second electrode portion 128a1 and the second electrode extending portion 128a2 may also adopt the same material or different materials, and is not limited by the invention. In the embodiment, the first electrode extending portion 126a2 respectively extends upward from the first electrode portion 126a1 and extends along a direction away from the second electrode portion 128a1, and the second electrode extending portion 128a2 respectively extends upward from the second electrode portion 128a1 and extends along a direction away from the first electrode portion 126a1.

Moreover, a material of the encapsulant 130a is, for example, a transparent inorganic material or organic material, where the inorganic material includes but is not limited to glass or ceramic, and the organic material includes but is not limited to silicone, epoxy resin, or various resins. The light emitting device 100a further includes at least one wavelength conversion material, where the wavelength conversion material includes but is not limited to a fluorescent material or a quantum dot material. The wavelength conversion material 134a can be doped in the encapsulant 130a for changing a wavelength of the light emitted by the light emitting unit 120a. In other embodiments of the invention, a wavelength conversion material layer can be directly formed on a surface of the light emitting unit 120a, and at least a part of the first electrode 126a and a part of the second electrode 128a are exposed, and the wavelength conversion material layer is located between the encapsulant 130a and the light emitting unit 120a, and a method for forming the wavelength conversion material layer includes but is not limited to spray coating or adhering. In another embodiment of the invention, the wavelength conversion material layer can be formed on the surface of the encapsulant 130a, and at least a part of the first electrode 126a and a part of the second electrode 128a are exposed, and the encapsulant 130a is located between the wavelength conversion material layer and the light emitting unit 120a, and a method for forming the wavelength conversion material layer includes but is not limited to spray coating or adhering. Certainly, in other embodiments, the light emitting device 100a may not include the wavelength conversion material, which is still a technical scheme adopted by the invention without departing from the protection range of the invention.

In brief, since the first electrode 126a and the second electrode 128a of the embodiment have the first electrode extending portion 126a2 and the second electrode extending portion 128a2 covering the upper surface 132a of the encapsulant 130a, compared to the conventional design of the first electrode and the second electrode, the light emitting device 100a of the embodiment has a larger electrode area. Moreover, when the light emitting device 100a is to be assembled to an external circuit (not shown), the design of the first electrode 126a and the second electrode 128a avails improving the alignment accuracy of the LED package in assembling and avoiding a conventional poor electrode contact. Specifically, since the first electrode extending portion 126a2 and the second electrode extending portion 128a2 respectively enlarge the areas of the first electrode portion 126a1 and the second electrode portion 128a1, when the light emitting device 100a is bonded to a circuit board through a solder paste, the situation of short circuit caused by overflow of the solder paste is mitigated or avoided, so as to ensure bonding reliability. In addition, in some embodiments, the light emitting device 100a may also be electrically connected to the external circuit through an anisotropic conductive layer. For example, the first electrode 126a and the second electrode 128a of the light emitting device 100a may be electrically connected to the external circuit through an anisotropic conductive paste or an anisotropic conductive film.

It should be noted that in the embodiment, an edge of the first electrode extending portion 126a2 and an edge of the second electrode extending portion 128a2 are aligned with an edge of the encapsulant 130a and an edge of the light transmissive layer 110. Other than that the electrode area is enlarged to increase the alignment accuracy, such design can be simpler in a manufacturing process, so as to save a manufacturing time. The reason is that the encapsulant 130a is able to encapsulate a plurality of the light emitting units 120a having the first electrode portion 126a1 and the second electrode portion 128a1 in one process, and after the first electrode extending portion 126a2 and the second electrode extending portion 128a2 are simultaneously plated, a cutting process is performed to form the light emitting device 100a.

It should be noted that the reference numerals and a part of the contents in the previous embodiment are used in the following embodiments, in which identical reference numerals indicate identical or similar components, and repeated description of the same technical contents is omitted. For a detailed description of the omitted parts, reference can be found in the previous embodiment, and no repeated description is contained in the following embodiments.

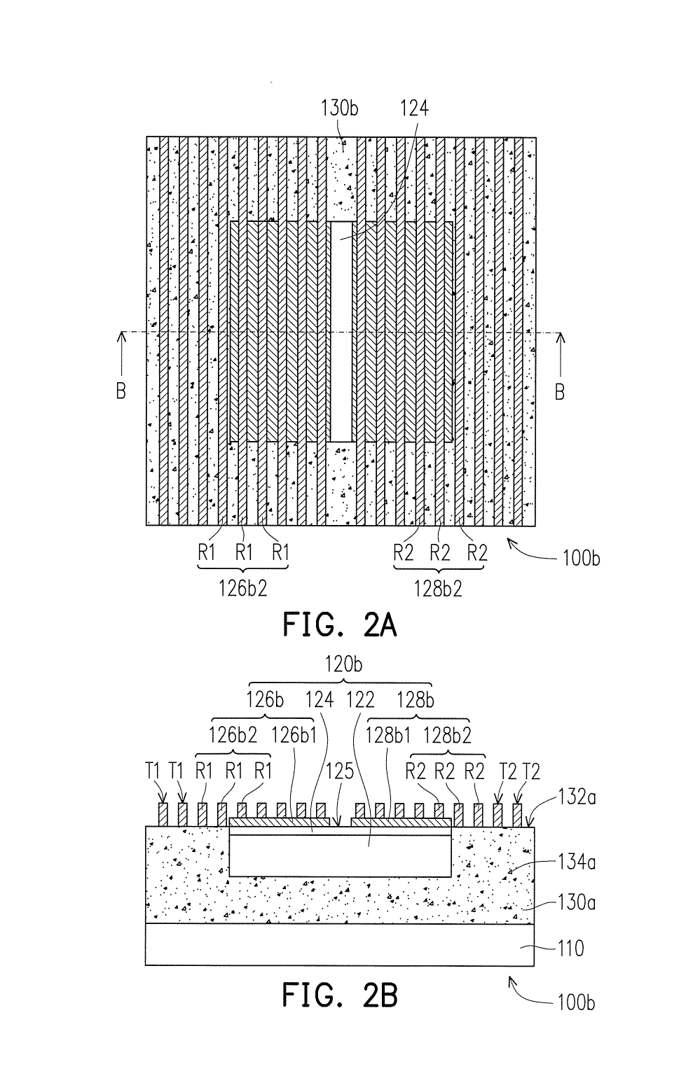

FIG. 2A is a schematic top view of a light emitting device according to another embodiment of the invention. FIG. 2B is a schematic cross-sectional view along a line B-B of FIG. 2A. Referring to FIG. 2A and FIG. 2B, a light emitting device 100b of the embodiment is similar to the light emitting device 100a of FIG. 1A and FIG. 1B, and a main difference therebetween is that a first electrode extending portion 126b2 of a first electrode 126b is composed of a plurality of first grating type electrodes R1, and a second electrode extending portion 128b2 of a second electrode 128b is composed of a plurality of second grating type electrodes R2. A part of the first grating type electrodes R1 and a part of the second grating type electrodes R2 respectively extend upward from a first electrode portion 126b1 and a second electrode portion 128b1, and a part of the first grating type electrodes R1 and a part of the second grating type electrodes R2 are disposed on the upper surface 132a of the encapsulant 130a.

The first grating type electrodes R1 are arranged in intervals (for example, equally spaced) and expose a part of the first electrode portion 126b1 and a part of the encapsulant 130a. The second grating type electrodes R2 are arranged in intervals (for example, equally spaced) and expose a part of the second electrode portion 128b1 and a part of the encapsulant 130a. Particularly, each of the first grating type electrodes R1 has a first top surface T1, and each of the second grating type electrodes R2 has a second top surface T2. The first top surfaces T1 of the first gating type electrodes R1 and the second top surfaces T2 of the second grating type electrodes R2 are substantially coplanar. In this way, when the light emitting device 100b is subsequently assembled to an external circuit (not shown), the design of the first electrode 126a and the second electrode 128b of the light emitting unit 120b can provide a more preferable assembling flatness and a larger electrode area to facilitate subsequent assembling of the light emitting device 100b. In some embodiments, the light emitting device 100b may also be electrically connected to the external circuit through an anisotropic conductive layer. For example, the first electrode 126b and the second electrode 128b of the light emitting device 100b may be electrically connected to the external circuit through an anisotropic conductive paste or an anisotropic conductive film.

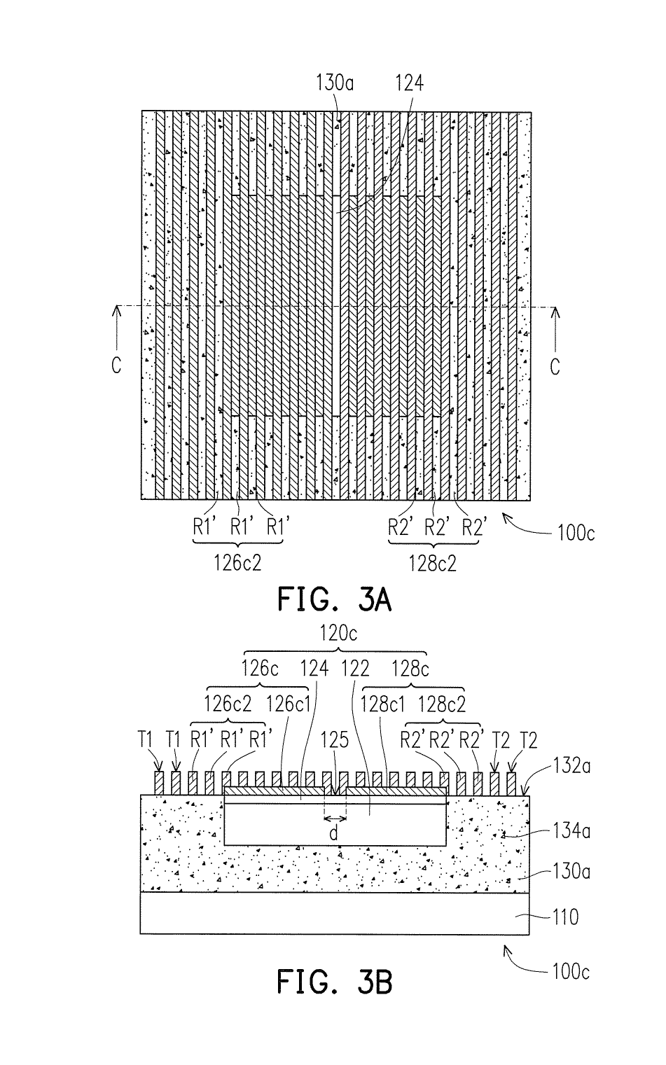

FIG. 3A is a schematic top view of a light emitting device according to another embodiment of the invention. FIG. 3B is a schematic cross-sectional view along a line C-C of FIG. 3A. Referring to FIG. 3A and FIG. 3B, a light emitting device 100c of the embodiment is similar to the light emitting device 100b of FIG. 2A and FIG. 2B, and a main difference therebetween is that a first electrode extending portion 126c2 of the embodiment is composed of a plurality of first grating type electrodes R1′, and a second electrode extending portion 128c2 is composed of a plurality of second grating type electrodes R2′, where the first grating type electrodes R1′ and the second grating type electrodes R2′ are further disposed at the interval d between a first electrode 126c and a second electrode 128c. In this way, the electrode area of a light emitting unit 120c may extend to the encapsulant 130a from the epitaxial structure layer 124, such that the light emitting device 100c has a larger electrode area to achieve a simple manufacturing process, and avails improving the alignment accuracy of the subsequent assembling process. It should be noted that the connection between the grating type electrodes and the circuit board can be implemented through an anisotropic conductive adhesive. For example, the first electrode 126c and the second electrode 128c of the light emitting device 100c may be electrically connected to the external circuit through an anisotropic conductive paste or an anisotropic conductive film.

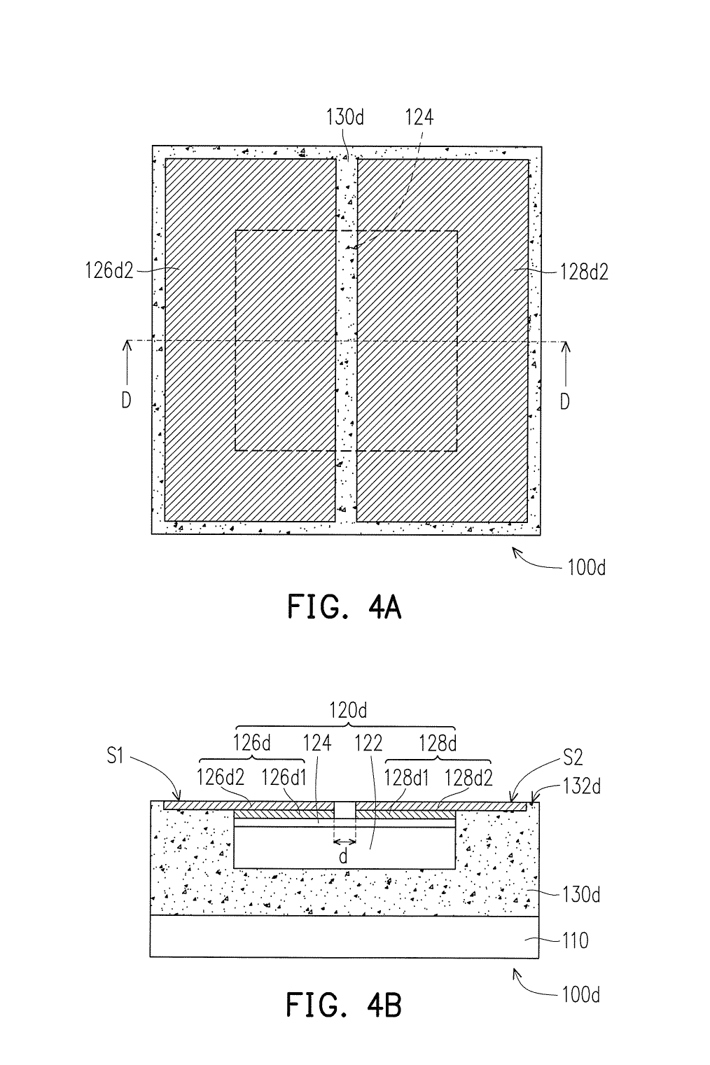

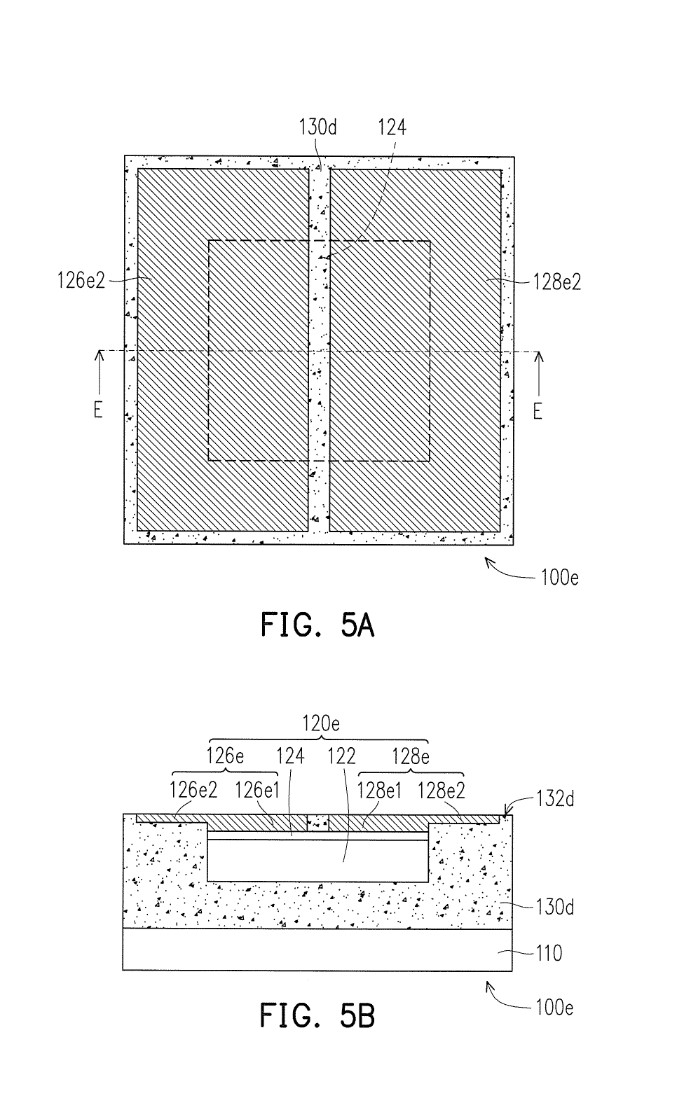

FIG. 4A is a schematic top view of a light emitting device according to another embodiment of the invention. FIG. 4B is a schematic cross-sectional view along a line D-D of FIG. 4A. Referring to FIG. 4A and FIG. 4B, a light emitting device 100d of the embodiment is similar to the light emitting device 100a of FIG. 1A and FIG. 1B, and a main difference therebetween is that an encapsulant 130d of the embodiment further wraps a first electrode 126d and a second electrode 128d and exposes upper surfaces of the electrodes, and the encapsulant 130d fills up the interval d between the first electrode 126d and the second electrode 128d, where a sidewall of a first electrode extending portion 126d2 and a sidewall of a second electrode extending portion 128d2 are also wrapped by the encapsulant 130d. Moreover, the edge of the first electrode extending portion 126d2 and the edge of the second electrode extending portion 128d2 are retracted from the edge of the encapsulant 130d and the edge of the light transmissive layer 110. A first upper surface S1 of the first electrode extending portion 126d2 and a second upper surface S2 of the second electrode extending portion 128d2 are substantially coplanar with an upper surface 132d of the encapsulant 130d. Namely, the first electrode extending portion 126d2 is disposed on the first electrode portion 126d1, and the first upper surface S1 of the first electrode extending portion 126d2 is substantially coplanar with the upper surface 132d of the encapsulant 130d. The second electrode extending portion 128d2 is disposed on the second electrode portion 128d1, and the second upper surface S2 of the second electrode extending portion 128d2 is substantially coplanar with the upper surface 132d of the encapsulant 130d. In this way, when the light emitting device 100d is electrically connected to an external circuit (not shown), the design of the first electrode 126d and the second electrode 128d of the light emitting unit 120d makes the light emitting device 100d free of an assembling gap in assembling, so as to effectively prevent moisture and oxygen from entering the light emitting device 100d. In some embodiments, the light emitting device 100d may also be electrically connected to the external circuit through an anisotropic conductive layer. For example, the first electrode 126d and the second electrode 128d of the light emitting device 100d may be electrically connected to the external circuit through an anisotropic conductive paste or an anisotropic conductive film.

FIG. 5A is a schematic top view of a light emitting device according to another embodiment of the invention. FIG. 5B is a schematic cross-sectional view along a line E-E of FIG. 5A. Referring to FIG. 5A and FIG. 5B, a light emitting device 100e of the embodiment is similar to the light emitting device 100d of FIG. 4A and FIG. 4B, and a main difference therebetween is that a first electrode extending portion 126e2 and a first electrode portion 126e1 of the embodiment have a seamless connection therebetween, and a second electrode extending portion 128e2 and a second electrode portion 128e1 have a seamless connection therebetween. Namely, the first electrode extending portion 126e2 and the first electrode portion 126e1 of a first electrode 126e of a light emitting unit 120e are formed integrally, and the second electrode extending portion 128e2 and the second electrode portion 128e1 of a second electrode 128e are formed integrally, such that integrity of the light emitting device 100e is more desirable and the light emitting device exhibits a more preferable reliability. In some embodiments, the light emitting device 100e may also be electrically connected to the external circuit through an anisotropic conductive layer. For example, the first electrode 126e and the second electrode 128e of the light emitting device 100e may be electrically connected to the external circuit through an anisotropic conductive paste or an anisotropic conductive film.

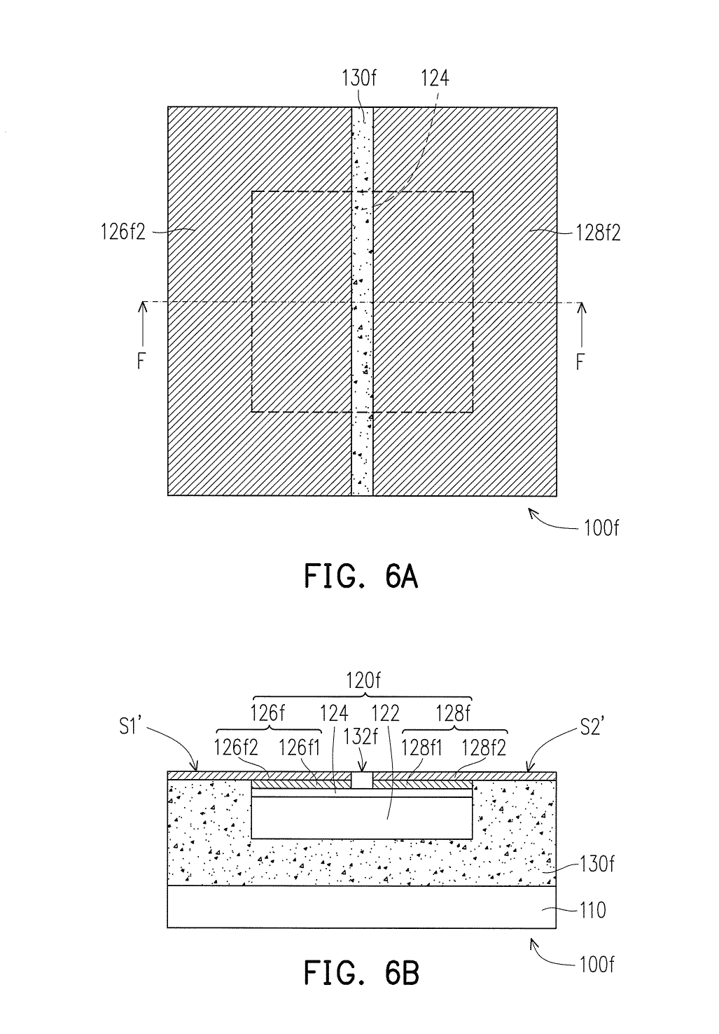

FIG. 6A is a schematic top view of a light emitting device according to another embodiment of the invention. FIG. 6B is a schematic cross-sectional view along a line F-F of FIG. 6A. Referring to FIG. 6A and FIG. 6B, a light emitting device 100f of the embodiment is similar to the light emitting device 100d of FIG. 4A and FIG. 4B, and a main difference therebetween is that an edge of a first electrode extending portion 126f2 and an edge of a second electrode extending portion 128f2 are aligned with an edge of an encapsulant 130f and the edge of the light transmissive unit 110, and are not wrapped by the encapsulant 130f. Now, the first electrode extending portion 126f2 of the light emitting unit 120f is disposed on the first electrode portion 126f1, and a first upper surface S1′ of the first electrode extending portion 126f2 is substantially coplanar with an upper surface 132f of the encapsulant 130f. The second electrode extending portion 128f2 of the light emitting unit 120f is disposed on the second electrode portion 128f1, and a second upper surface S2′ of the second electrode extending portion 128f2 is substantially coplanar with the upper surface 132f of the encapsulant 130f. In some embodiments, the light emitting device 100f may also be electrically connected to the external circuit through an anisotropic conductive layer. For example, the first electrode 126f and the second electrode 128f of the light emitting device 100f may be electrically connected to the external circuit through an anisotropic conductive paste or an anisotropic conductive film.

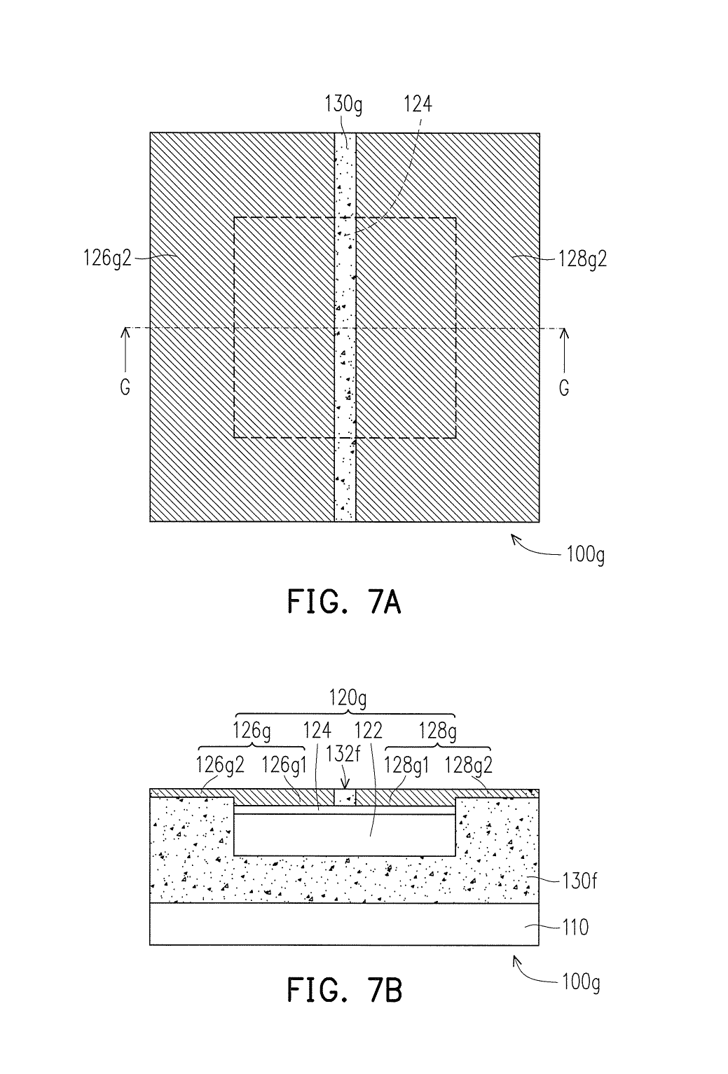

FIG. 7A is a schematic top view of a light emitting device according to another embodiment of the invention. FIG. 7B is a schematic cross-sectional view along a line G-G of FIG. 7A. Referring to FIG. 7A and FIG. 7B, a light emitting device 100g of the embodiment is similar to the light emitting device 100f of FIG. 6A and FIG. 6B, and a main difference therebetween is that a first electrode extending portion 126g2 and the a electrode portion 126g1 of the embodiment have a seamless connection therebetween, and a second electrode extending portion 128g2 and a second electrode portion 128g1 have a seamless connection therebetween. Namely, the first electrode extending portion 126g2 and the first electrode portion 126g1 of a first electrode 126g of the light emitting unit 120g are formed integrally, and the second electrode extending portion 128g2 and the second electrode portion 128g1 of a second electrode 128g are formed integrally. In some embodiments, the light emitting device 100g may also be electrically connected to the external circuit through an anisotropic conductive layer. For example, the first electrode 126g and the second electrode 128g of the light emitting device 100g may be electrically connected to the external circuit through an anisotropic conductive paste or an anisotropic conductive film.

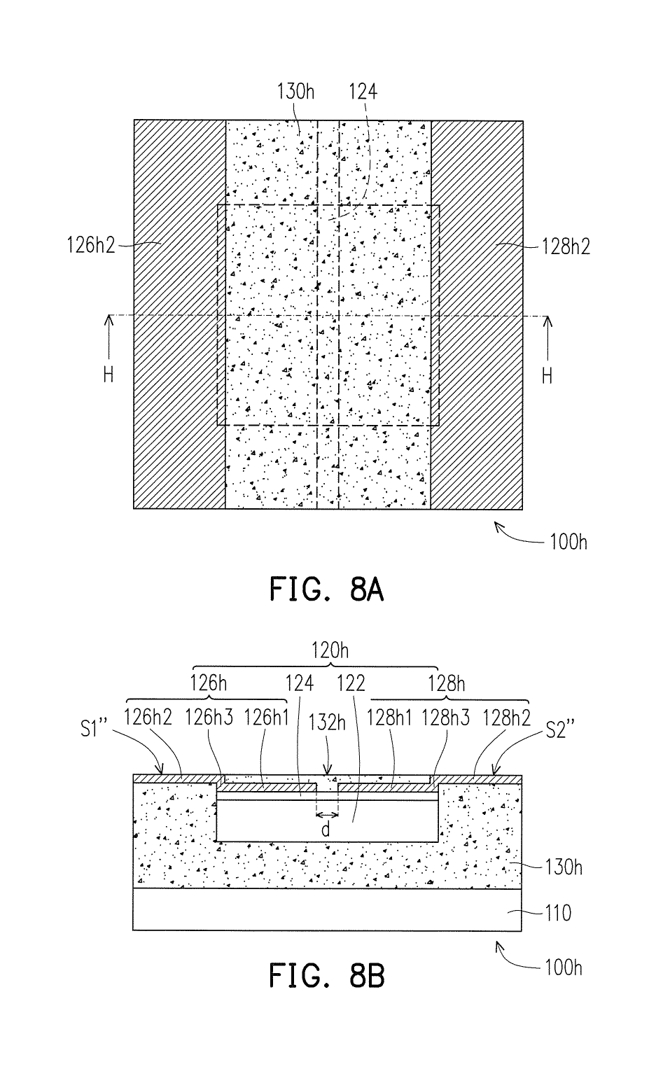

FIG. 8A is a schematic top view of a light emitting device according to another embodiment of the invention. FIG. 8B is a schematic cross-sectional view along a line H-H of FIG. 8A. Referring to FIG. 8A and FIG. 8B, a light emitting device 100h of the embodiment is similar to the light emitting device 100g of FIG. 7A and FIG. 7B, and a main difference therebetween is that a first electrode 126h of a light emitting unit 120h of the embodiment further includes a first connection portion 126h3 connecting a first electrode portion 126h1 and a first electrode extending portion 126h2. An extending direction of the first connection portion 126h3 is perpendicular to an extending direction of the first electrode portion 126h1 and an extending direction of the first electrode extending portion 126h2. The first electrode portion 126h1, the first connection portion 126h3 and the first electrode extending portion 126h2 may have a seamless connection therebetween. A second electrode 128h of the light emitting unit 120h further includes a second connection portion 128h3 connecting a second electrode portion 128h1 and a second electrode extending portion 128h2. An extending direction of the second connection portion 128h3 is perpendicular to an extending direction of the second electrode portion 128h1 and an extending direction of the second electrode extending portion 128h2. The second electrode portion 128h1, the second connection portion 128h3 and the second electrode extending portion 128h2 may have a seamless connection therebetween. A first upper surface S1″ of the first electrode extending portion 126h2 and a second upper surface S2″ of the second electrode extending portion 128h2 are substantially coplanar with an upper surface 132h of the encapsulant 130h. The encapsulant 130h fills up the interval d between the first electrode 126h and the second electrode 128h. An edge of the first electrode extending portion 126h2 and an edge of the second electrode extending portion 128h2 are aligned with an edge of the encapsulant 130h and the edge of the light transmissive layer 110. In some embodiments, the light emitting device 100h may also be electrically connected to the external circuit through an anisotropic conductive layer. For example, the first electrode 126h and the second electrode 128h of the light emitting device 100h may be electrically connected to the external circuit through an anisotropic conductive paste or an anisotropic conductive film.

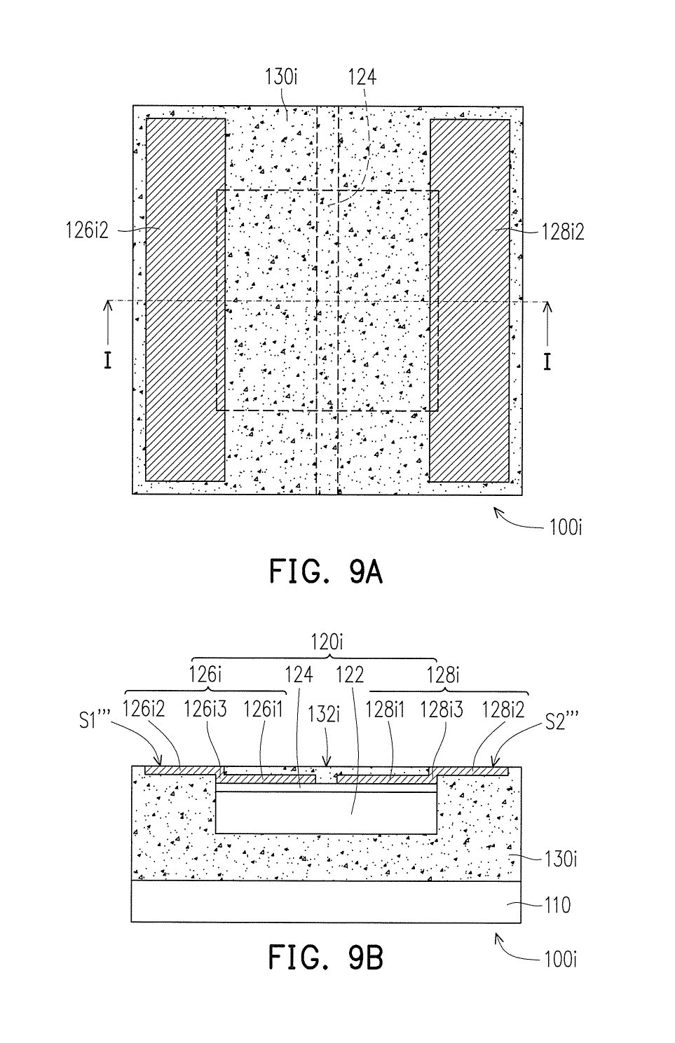

FIG. 9A is a schematic top view of a light emitting device according to another embodiment of the invention. FIG. 9B is a schematic cross-sectional view along a line I-I of FIG. 9A. Referring to FIG. 9A and FIG. 9B, a light emitting device 100i of the embodiment is similar to the light emitting device 100h of FIG. 8A and FIG. 8B, and a main difference therebetween is that a sidewall of a first electrode extending portion 126i2 and a sidewall of a second electrode extending portion 128i2 are wrapped by an encapsulant 130i in this embodiment. Namely, a first electrode 126i, a second electrode 128i, the epitaxial structure layer 124 and the substrate 122 of the light emitting unit 120i are encapsulated by the encapsulant 130i, though upper surfaces of the electrodes are exposed. The first electrode extending portion 126i2 of the first electrode 126i is connected to a first electrode portion 126i1 through a first connection portion 126i3, and a first surface S1′″ of the first electrode extending portion 126i2 is substantially coplanar with an upper surface 132i of the encapsulant 130i. Moreover, the second electrode extending portion 128i2 of the second electrode 128i is connected to a second electrode portion 128i1 through a second connection portion 128i3, and a second surface S2′″ of the second electrode extending portion 128i2 is substantially coplanar with the upper surface 132i of the encapsulant 130i. In some embodiments, the light emitting device 100i may also be electrically connected to the external circuit through an anisotropic conductive layer. For example, the first electrode 126i and the second electrode 128i of the light emitting device 100i may be electrically connected to the external circuit through an anisotropic conductive paste or an anisotropic conductive film.

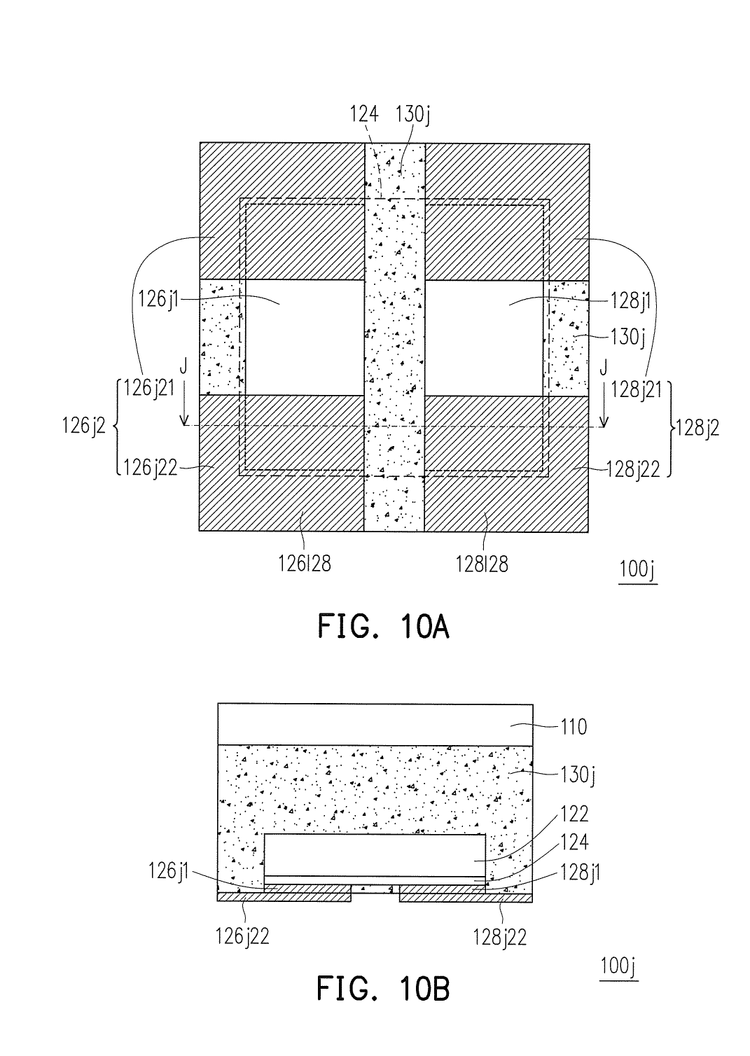

FIG. 10A is a schematic top view of a light emitting device according to another embodiment of the invention, and FIG. 10B is a schematic cross-sectional view along a line J-J of FIG. 10A. Referring to FIGS. 10A and 10B, a light emitting device 100j of the embodiment is similar to the light emitting device 100a of FIG. 1A, and differences therebetween are as follows. In the light emitting device 100j of the embodiment, a first electrode extending portion 126j2 includes a plurality of first sub-electrodes 126j21 and 126j22 separated from each other, and the second electrode extending portion 128j2 includes a plurality of second sub-electrodes 128j21 and 128j22 separated from each other. In the embodiment, the first sub-electrodes 126j21 and 126j22 are located at two adjacent corners of the encapsulant, and the second sub-electrodes 128j21, 128j22 are located at the other two adjacent corners of the encapsulant. In other words, the first sub-electrodes 126j21 and 126j22 extend from an edge of a first electrode portion 126j1 along a direction away from a second electrode portion 128j1, and the second sub-electrodes 128j21 and 128j22 extend from an edge of a second electrode portion 128j 1 along a direction away from the first electrode portion 126j1, so that the sub-electrodes 126j21, 126j22, 128j21, and 128j22 respectively extend to four corners of an upper surface of the light emitting device 100j. Moreover, in the embodiment, an encapsulant 130j encapsulates the first electrode portion 126j 1 and the second electrode portion 128j1, and the sub-electrodes 126j21, 126j22, 128j21 and 128j22 extend to cover the encapsulant 130j. In the embodiment, the light emitting device 100j may further include the light transmissive layer 110, and the encapsulant 130j is disposed on the light transmissive layer 110. Compared to FIG. 1B, FIG. 10B only illustrates a situation that the light emitting device 100j is turned over for flip-chip bonding.

In the light emitting device 100j of the embodiment, the sub-electrodes 126j21, 126j22, 128j21, 128j22 configured at the four corners of the upper surface of the light emitting device 100j may be respectively bonded to the circuit board through four solder pastes, and the four solder pastes configured at the four corners may disperse a stress in case of reflow. In this way, after the light emitting device 100j is bonded to the circuit board and cooled down, the light emitting device 100j is not shifted an angle relative to a predetermined position, so as to ensure a yield rate of the bonding process. In some embodiments, the light emitting device 100j may also be electrically connected to the external circuit through an anisotropic conductive layer. For example, the first electrode (the first electrode portion 126j1 and the first electrode extending portion 126j2) and the second electrode (the second electrode portion 128j1 and the second electrode extending portion 128j2) of the light emitting device 100j may be electrically connected to the external circuit through an anisotropic conductive paste or an anisotropic conductive film.

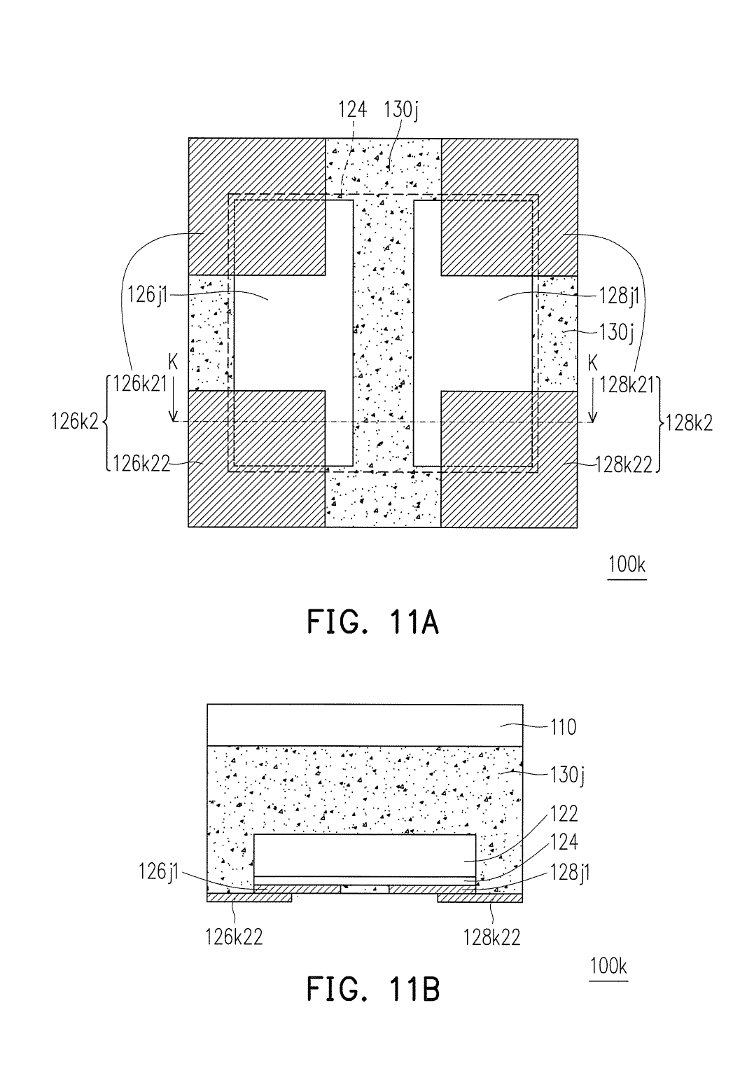

FIG. 11A is a schematic top view of a light emitting device according to another embodiment of the invention, and FIG. 11B is a schematic cross-sectional view along a line K-K of FIG. 11A. Referring to FIGS. 11A and 11B, a light emitting device 100k of the embodiment is similar to the light emitting device 100j of FIGS. 10A and 10B, and differences therebetween are as follows. In the light emitting device 100k of the embodiment, areas that the first sub-electrodes 126k21, 126k22 of the first electrode extending portion 126k2 respectively cover a first electrode portion 126j1 are relatively small, and the first sub-electrodes 126k21, 126k22 respectively cover two adjacent corners of the first electrode portion 126j1, where the two adjacent corners are respectively close to two adjacent corners of an upper surface of the light emitting device 100k. Moreover, areas that the second sub-electrodes 128k21, 128k22 of the second electrode extending portion 128k2 respectively cover the second electrode portion 128j1 are relatively small, and the second sub-electrodes 128k21, 128k22 respectively cover two adjacent corners of the second electrode portion 128j 1, where the two adjacent corners are respectively close to the two adjacent corners of the upper surface of the light emitting device 100k. In some embodiments, the light emitting device 100k may also be electrically connected to the external circuit through an anisotropic conductive layer. For example, the first electrode (the first electrode portion 126j 1 and the first electrode extending portion 126k2) and the second electrode (the second electrode portion 128j1 and the second electrode extending portion 128k2) of the light emitting device 100k may be electrically connected to the external circuit through an anisotropic conductive paste or an anisotropic conductive film.

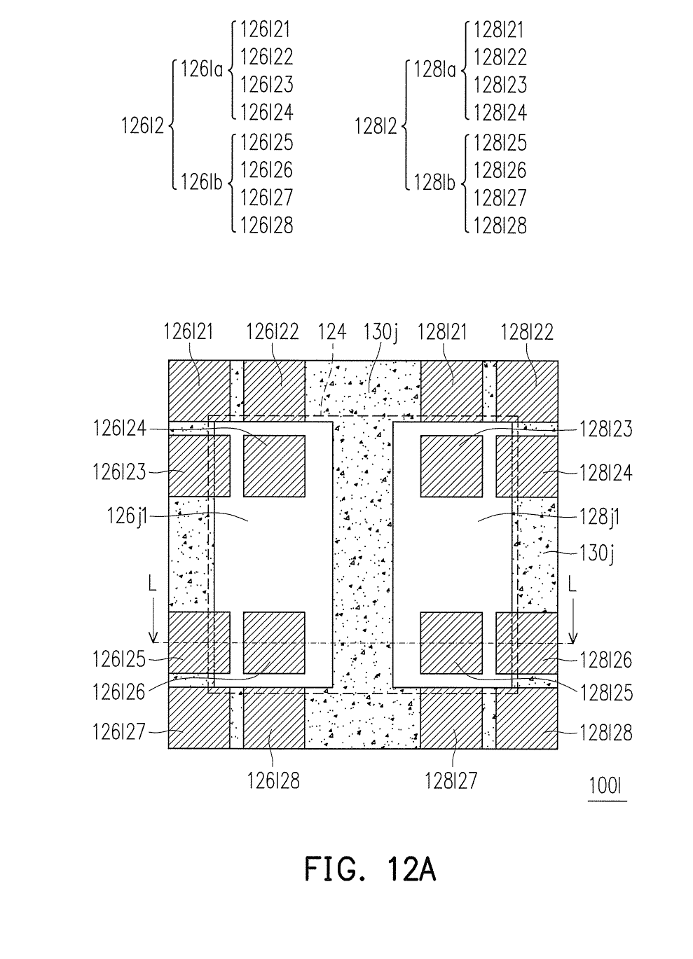

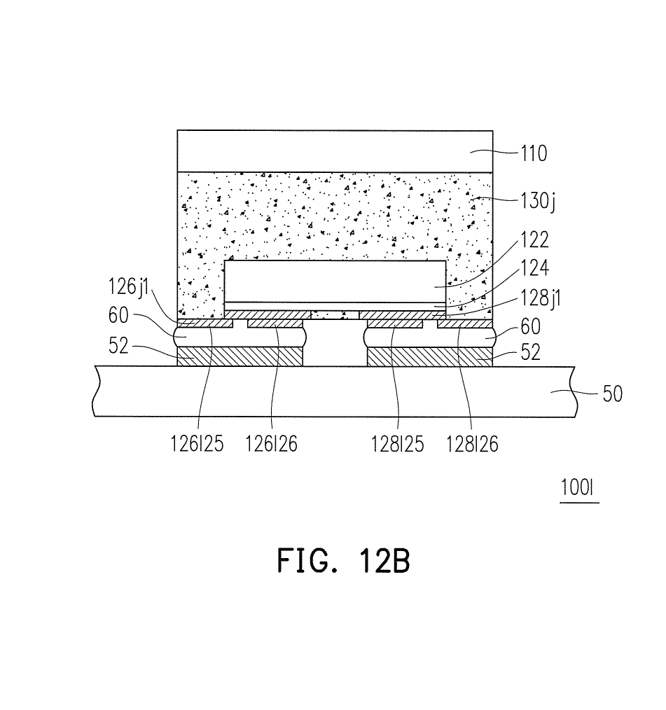

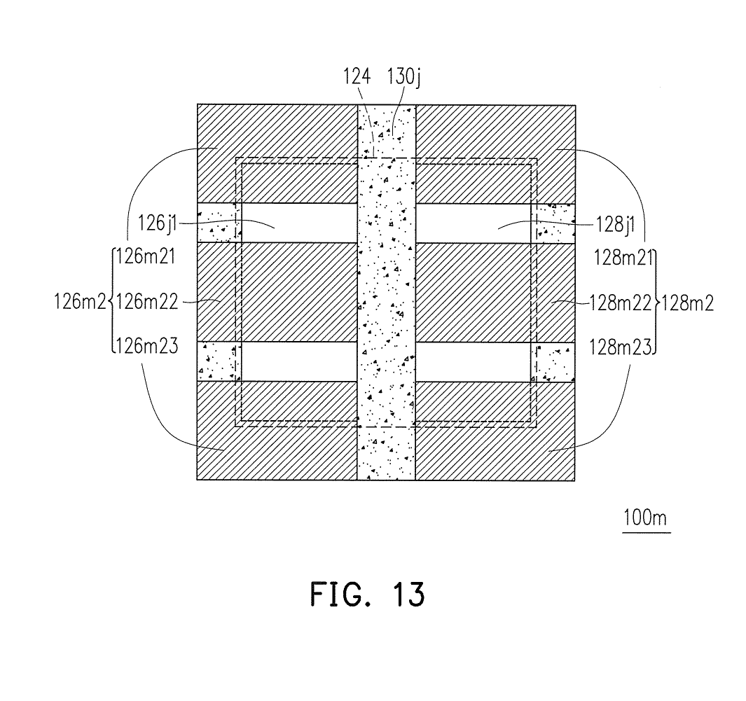

FIG. 12A is a schematic top view of a light emitting device according to another embodiment of the invention, and FIG. 12B is a schematic cross-sectional view illustrating a light emitting device bonded to a circuit board through flip-chip bonding along a line L-L of FIG. 12A. Referring to FIGS. 12A and 12B, a light emitting device 100l of the embodiment is similar to the light emitting device 100k of FIGS. 11A and 11B, and differences therebetween are as follows. In the light emitting device 100l of the embodiment, first sub-electrodes 126l21-126l28 of a first electrode extending portion 126l2 are grouped into two first sub-electrode groups 126la and 126lb. Each of the first sub-electrode groups 126la and 126lb respectively includes a part of the first sub-electrodes. For example, as shown in FIG. 12A, the first sub-electrode group 126la includes four first sub-electrodes 126l21-126l24, and the first sub-electrode group 126lb includes four first sub-electrodes 126l25-126l28. Moreover, second sub-electrodes 128l21-128l28 of a second electrode extending portion 128l2 are grouped into two second sub-electrode groups 128la and 128lb, where each of the second sub-electrode groups 128la and 128lb respectively includes a part of the second sub-electrodes. For example, as shown in FIG. 12A, the second sub-electrode group 128la includes four second sub-electrodes 128l21-128l24, and the second sub-electrode group 128lb includes four second sub-electrodes 128l25-128l28. In the embodiment, the two first sub-electrode groups 126la and 126lb are respectively disposed at two adjacent corners on an upper surface of the light emitting device 100l, and the two second sub-electrode groups 128la and 128lb are respectively disposed at the other two adjacent corners on the upper surface of the light emitting device 100l.

The light emitting device 100l may be bonded to the circuit board 50 through flip-chip bonding. For example, the two first sub-electrode groups 126la, 126lb are respectively bonded to electrode pads 52 (for example, the electrode pads 52 located at the left as shown in FIG. 12B) on the circuit board 50 through two cured solder pastes 60, and the two second sub-electrode groups 128la, 128lb are respectively bonded to electrode pads 52 (for example, the electrode pads 52 located at the right as shown in FIG. 12B) on the circuit board 50 through two cured solder pastes 60. Since the solder pastes 60 may be filled in an interval between two adjacent sub-electrodes before curing, a bonding force between the solder pastes 60 and the first sub-electrodes 126l21-126l28 and a bonding force between the solder pastes 60 and the second sub-electrodes 128l21-128l28 may be effectively enhanced, so as to improve reliability of bonding of the light emitting device 100l to the circuit board 50. In some embodiments, the light emitting device 100l may also be electrically connected to the external circuit through an anisotropic conductive layer. For example, the first electrode (the first electrode portion 126j1 and the first electrode extending portion 126l2) and the second electrode (the second electrode portion 128j 1 and the second electrode extending portion 128l2) of the light emitting device 100l may be electrically connected to the external circuit through an anisotropic conductive paste or an anisotropic conductive film.

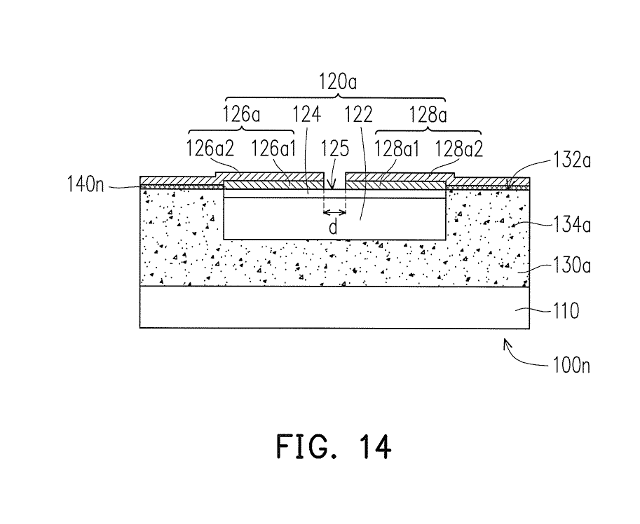

FIG. 13 is a schematic top view of a light emitting device according to another embodiment of the invention. Referring to FIG. 13, a light emitting device 100m of the embodiment is similar to the light emitting device 100j of FIG. 10A, and differences therebetween are as follows. In the light emitting device 100m of the embodiment, first sub-electrodes 126m21 and 126m23 of a first electrode extending portion 126m2 are respectively disposed at two adjacent corners on an upper surface of the light emitting device 100m, and a first sub-electrode 126m22 is disposed between the first sub-electrode 126m21 and the first sub-electrode 126m23. Moreover, second sub-electrodes 128m21 and 128m23 of a second electrode extending portion 128m2 are respectively disposed at other two adjacent corners on the upper surface of the light emitting device 100m, and a second sub-electrode 128m22 is disposed between the second sub-electrode 128m21 and the second sub-electrode 128m23. In other embodiments of the invention, the number and configuration of the first sub-electrodes and the second sub-electrodes can be modified, and is not limited by the invention. Moreover, in some embodiments, the light emitting device 100m may also be electrically connected to the external circuit through an anisotropic conductive layer. For example, the first electrode (the first electrode portion 126j1 and the first electrode extending portion 126m2) and the second electrode (the second electrode portion 128j1 and the second electrode extending portion 128m2) of the light emitting device 100m may be electrically connected to the external circuit through an anisotropic conductive paste or an anisotropic conductive film.

FIG. 14 is a schematic cross-sectional view of a light emitting device according to another embodiment of the invention. Referring to FIG. 14, a light emitting device 100n of the embodiment is similar to the light emitting device 100a of FIG. 1B, and differences therebetween are as follows. In the embodiment, the light emitting device 100n further includes a reflection layer 140n at least disposed on the upper surface 132a of the encapsulant 130a. In the embodiment, at least a part of the reflection layer 140n is disposed between the first electrode 126a and the upper surface 132a of the encapsulant 130a, and between the second electrode 128a and the upper surface 132a of the encapsulant 130a. To be specific, the reflection layer 140n may be disposed between the first electrode extending portion 126a2 and the upper surface 132a of the encapsulant 130a and between the second electrode extending portion 128a2 and the upper surface 132a of the encapsulant 130a. The reflection layer 140a is, for example, gold, aluminium, silver, nickel, titanium, distributed Bragg reflector (DBR), a resin layer doped with reflection particles with high reflectivity (for example, a silicone layer or an epoxy resin layer) or a combination thereof. The reflection layer 140n may reflect the light emitted by the light emitting unit 120a toward the light transmissive layer 110, such that the light may be emitted out of the light transmissive layer 110 more effectively. When the reflection layer 140n is made of an insulation material, the reflection layer 140n may be formed as a whole piece to cover the entire upper surface 132a of the encapsulant 130a. However, when the reflection layer 140n is made of a conductive material or a metal material, the part of the reflection layer 140n disposed under the first electrode extending portion 126a2 has to be separated from the part of the reflection layer 140n disposed under the second electrode extending portion 128a2 to avoid a short circuit. In some embodiments, the light emitting device 100n may also be electrically connected to the external circuit through an anisotropic conductive layer. For example, the first electrode 126a and the second electrode 128a of the light emitting device 100n may be electrically connected to the external circuit through an anisotropic conductive paste or an anisotropic conductive film.

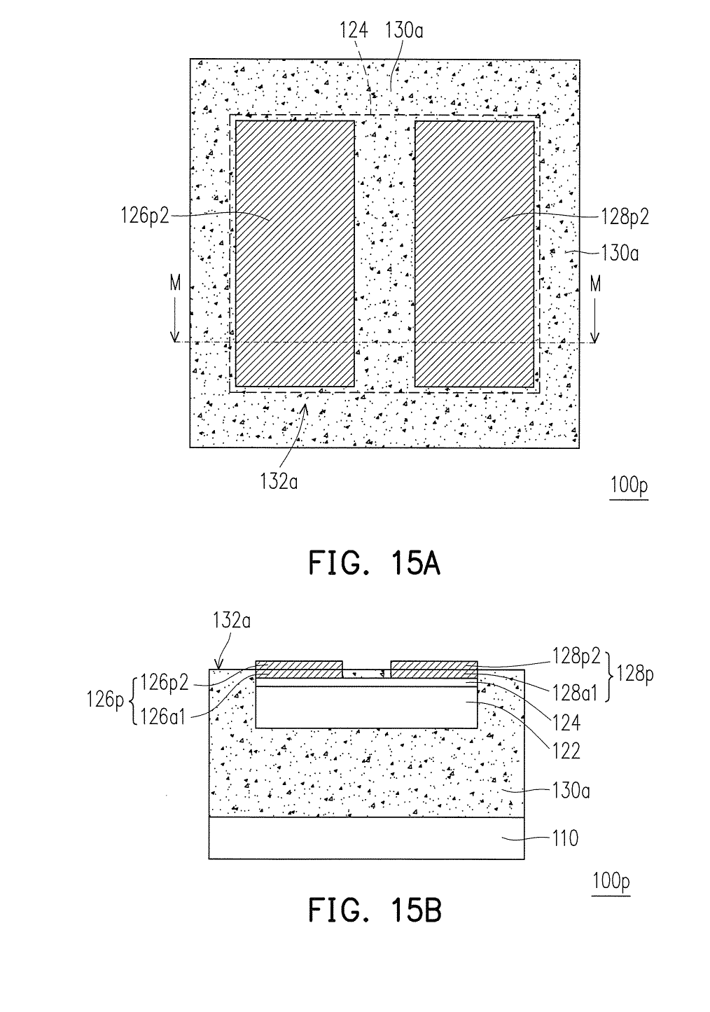

FIG. 15A is a top view of a light emitting device according to another embodiment of the invention. FIG. 15B is a cross-sectional view of the light emitting device of FIG. 15A viewing along a line M-M. Referring to FIG. 15A and FIG. 15B, a light emitting device 100p of the embodiment is similar to the light emitting device 100f of FIG. 6A and FIG. 6B, and differences therebetween are as follows. In the light emitting device 100p of the embodiment, a first electrode 126p and a second electrode 128p extend upward from the epitaxial structure layer 124 to protrude out from the upper surface 132a of the encapsulant 130a. In the embodiment, neither the first electrode 126p nor the second electrode 128p covers the upper surface 132a of the encapsulant 130a.

To be specific, a first electrode extending portion 126p2 of the first electrode 126p is disposed on a first electrode portion 126a1 and protrudes out from the upper surface 132a of the encapsulant 130a, and a second electrode extending portion 128p2 of the second electrode 128p is disposed on a second electrode portion 128a1 and protrudes out from the upper surface 132a of the encapsulant 130a. In the embodiment, neither the first electrode extending portion 126p2 nor the second electrode extending portion 128p2 covers the upper surface 132a of the encapsulant 130a. In addition, the first electrode extending portion 126p2 and the second electrode extending portion 128p2 are substantially coplanar. In another embodiment, the first electrode 126p and the second electrode 128p may also extend upward from the epitaxial structure layer 124 without protruding out from the upper surface 132a of the encapsulant 130a. For example, an upper surface of the first electrode extending portion 126p2 (i.e. the surface facing away from the epitaxial structure layer 124), an upper surface of the second electrode extending portion 128p2 (i.e. the surface facing away from the epitaxial structure layer 124) and the upper surface 132a of the encapsulant 130a are substantially coplanar.

In the embodiment, increasing heights of the first electrode 126p and the second electrode 128p by means of the first electrode extending portion 126p2 and the second electrode extending portion 128p2, avails a chip bonding process. In some embodiments, the light emitting device 100p may also be electrically connected to the external circuit through an anisotropic conductive layer. For example, the first electrode 126p and the second electrode 128p of the light emitting device 100p may be electrically connected to the external circuit through an anisotropic conductive paste or an anisotropic conductive film.

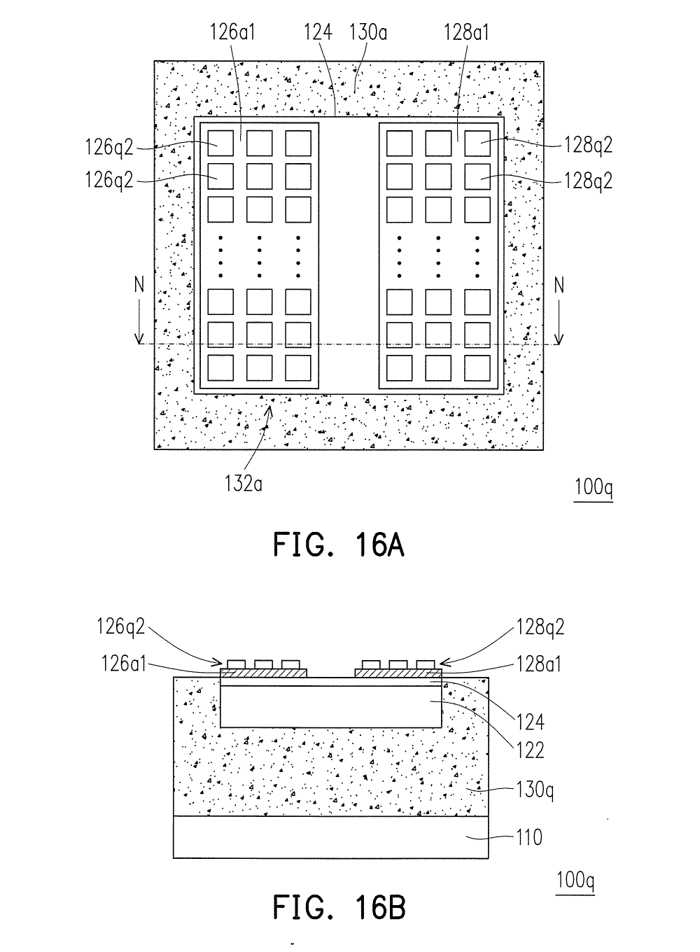

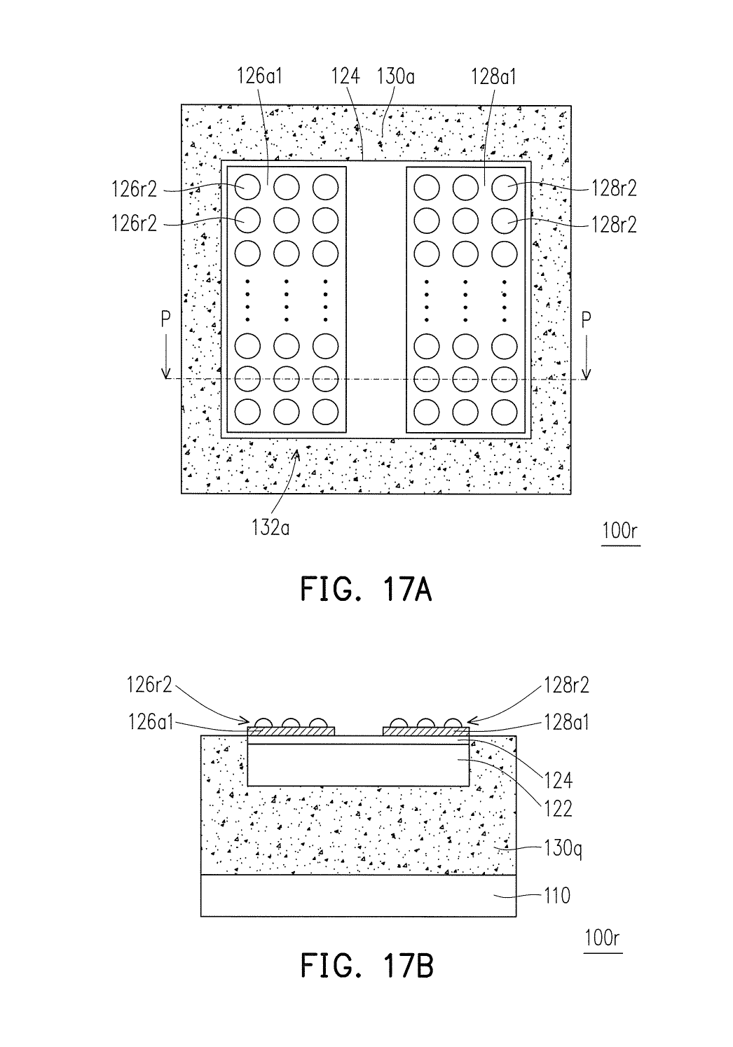

FIG. 16A is a top view of a light emitting device according to another embodiment of the invention. FIG. 16B is a cross-sectional view of the light emitting device viewing along a line N-N of FIG. 16A. Referring to FIG. 16A and FIG. 16B, a light emitting device 100q of the embodiment is similar to the light emitting device 100p of FIG. 15A and FIG. 15B, and differences therebetween are as follows. In the light emitting device 100q of the embodiment, the first electrode extending portion extending upward includes a plurality of first sub-electrodes 126q2 separated from each other, and the second electrode extending portion extending upward includes a plurality of second sub-electrodes 128q2 separated from each other. In some embodiments, the light emitting device 100q may also be electrically connected to the external circuit through an anisotropic conductive layer. For example, the first electrode (the first electrode portion 126a1 and a first sub-electrode 126q2) and the second electrode (the second electrode portion 128a1 and a second sub-electrode 128q2) of the light emitting device 100q may be electrically connected to the external circuit through an anisotropic conductive paste or an anisotropic conductive film.

FIG. 17A is a top view of a light emitting device according to another embodiment of the invention. FIG. 17B is a cross-sectional view of the light emitting device of FIG. 17A viewing along a line P-P. Referring to FIG. 17A and FIG. 17B, a light emitting device 100r of the embodiment is similar to the light emitting device 100q of FIG. 16A and FIG. 16B, and a main difference therebetween is that the first sub-electrodes 126q2 and the second sub-electrodes 128q2 of the light emitting device 100q are laminar electrodes, and first sub-electrodes 126r2 and second sub-electrodes 128r2 of the light emitting device 100r of the embodiment are spherical electrodes. The spherical electrodes may be formed by performing to a ball planting process. In some embodiments, the light emitting device 100r may also be electrically connected to the external circuit through an anisotropic conductive layer. For example, the first electrode (the first electrode portion 126a1 and a first sub-electrode 126r2) and the second electrode (the second electrode portion 128a1 and a second sub-electrode 128r2) of the light emitting device 100r may be electrically connected to the external circuit through an anisotropic conductive paste or an anisotropic conductive film.

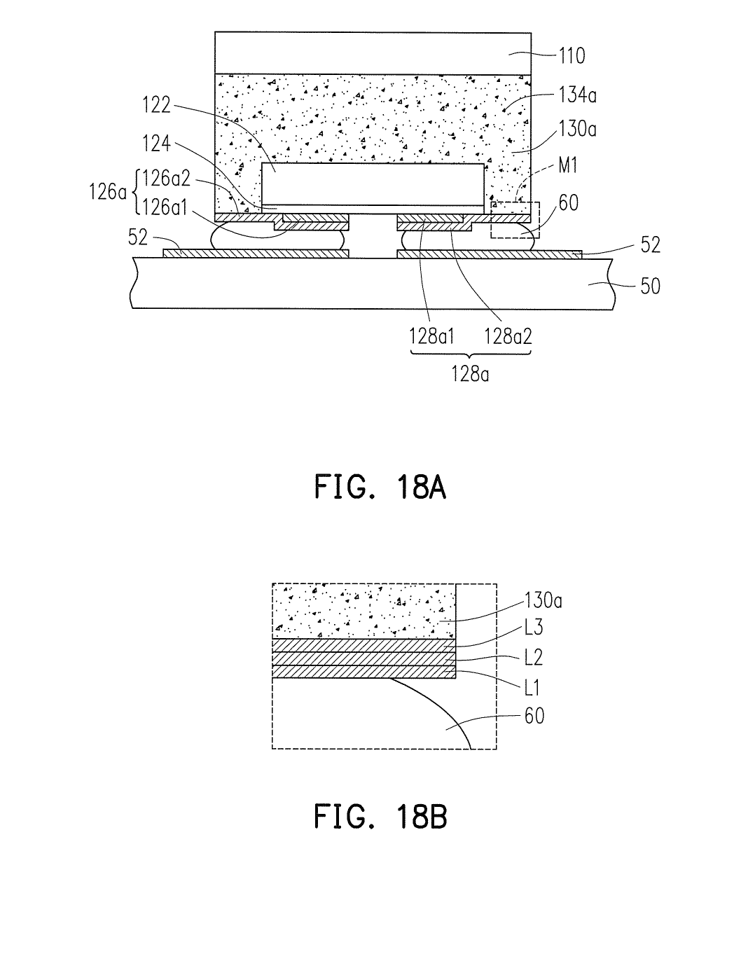

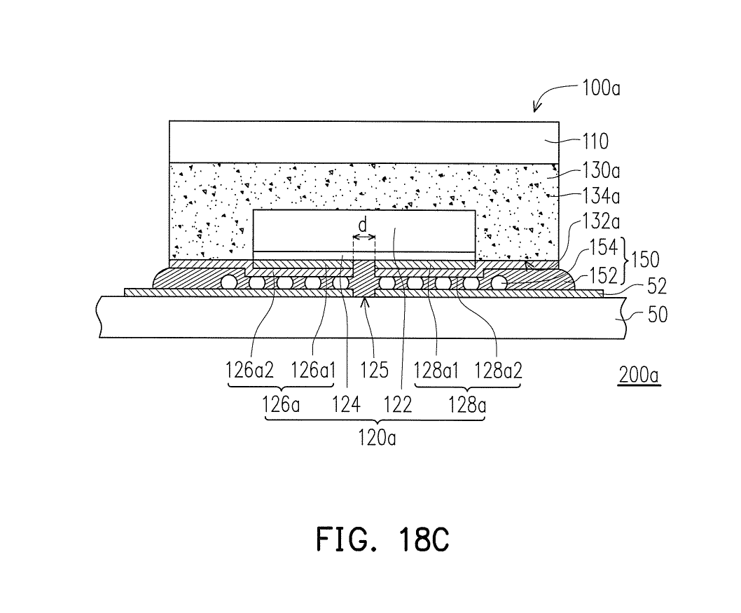

FIG. 18A is a schematic cross-sectional view according to an embodiment of the invention where the light emitting device of FIG. 1B is bonded to a circuit board through flip-chip bonding, and FIG. 18B is a partial enlarged of a region M1 of FIG. 18A. Referring to FIG. 18A and FIG. 18B, the light emitting device 100a can be bonded to the circuit board 50 through the flip-chip bonding manner. For example, the first electrode extending portion 126a2 and the second electrode extending portion 128a2 are respectively bonded to the two electrode pads 52 on the circuit board 50 through two cured solder pastes 60.

In the embodiment, each of the first electrode extending portion 126a2 and the second electrode extending portion 128a2 respectively includes an adhesion layer L1 and a barrier layer L2 disposed between the adhesion layer L1 and the encapsulant 130a. A material of the adhesion layer includes gold, tin, aluminium, silver, copper, indium, bismuth, platinum, gold-tin alloy, tin-silver alloy, tin-silver-copper alloy (Sn—Ag—Cu (SAC) alloy) or a combination thereof, and a material of the barrier layer includes nickel, titanium, tungsten, gold or an alloy of a combination thereof. The adhesion layer L1 is suitable to be bonded with the solder pastes 60, and the barrier layer L2 can effectively prevent the material of the solder pastes 60 from invading the encapsulant 130a to contaminate the light emitting device 100a during the bonding process.

In the embodiment, the first electrode extending portion 126a2 and the second electrode extending portion 128a2 further respectively include a reflection layer L3 at least disposed between the barrier layer L2 and the encapsulant 130a. The reflection layer L3 may reflect the light coming from the epitaxial structure layer 124 to improve a light usage rate. In the embodiment, a material of the reflection layer L3 includes gold, aluminium, silver, nickel, titanium or an alloy of a combination thereof.

FIG. 18C is a schematic cross-sectional view according to another embodiment of the invention where the light emitting device of FIG. 1B is bonded to a circuit board through flip-chip bonding. Referring to FIG. 18C, the light emitting device 100a may be bonded to the circuit board 50 through flip-chip bonding, so as to form a light emitting device 200a. In this embodiment, the light emitting device 200a includes the circuit board 50, the light emitting device 100a, and an anisotropic conductive layer 150. To be specific, the first electrode 126a and the second electrode 128a of the light emitting device 100a are bonded to the circuit board 50 through the anisotropic conductive layer 150. In addition, the first electrode 126a and the second electrode 128a are electrically connected with the electrode pads 52 on the circuit board 50.

In this embodiment, the anisotropic conductive layer 150 includes an insulating paste 152 and a plurality of conductors 154 dispersed in the insulating paste 152. To be specific, the anisotropic conductive layer 150 may be an anisotropic conductive adhesive (ACA), an anisotropic conductive film (ACF), or other materials having a conductive function and an adhesive function at the same time. The invention does not intend to impose a limitation in this regard. In this embodiment, the anisotropic conductive layer 150 may be an anisotropic conductive adhesive, for example. By pressing or heating corresponding positions of the anisotropic conductive layer 150 at the first electrode 126a and the corresponding electrode pad 52, the conductors 154 may be connected to each other and contact the first electrode 126a and the corresponding electrode pad 52, so as to electrically connect the first electrode 126a and the corresponding electrode pad 52. In addition, by heating or pressing corresponding positions of the anisotropic conductive layer 150 at the second electrode 128a and the corresponding electrode pad 52, the second electrode 128a and the corresponding electrode pad 52 may be electrically connected. In this embodiment, at positions on the anisotropic conductive layer 150 that are not pressed or heated, the conductors 154 are unable to be electrically connected. Therefore, a short circuit does not occur easily in a horizontal direction in the light emitting device 200a.

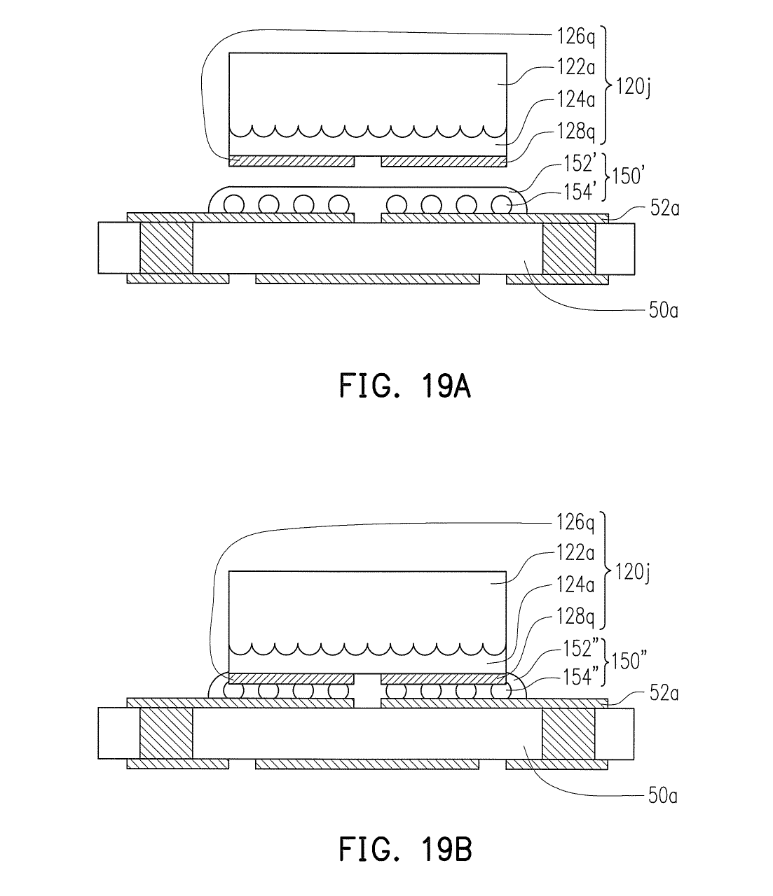

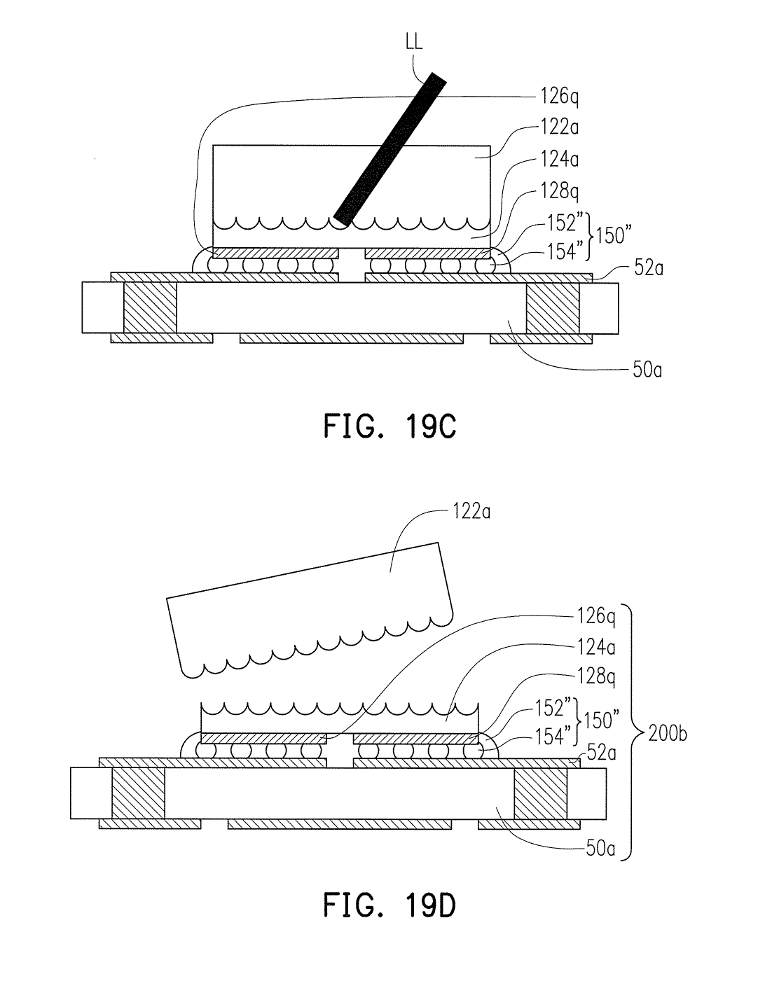

FIGS. 19A to 19D are schematic views illustrating fabrication of a light emitting device according to an embodiment of the invention. Referring to FIG. 19A, in this embodiment, a fabricating method of the light emitting device includes providing a circuit board 50a. The circuit board 50a includes a plurality of electrode pads 52a and a circuit structure (not shown) connecting the electrode pads 52a. Specifically, the circuit board 50a may be a printed circuit board (PCB), a submount, a metal core printed circuit board (MCPCB), or other carrying boards having a conductive circuit. However, the invention does not intend to impose a limitation in this regard. Then, a light emitting unit 120j is provided. The light emitting unit 120j includes an epitaxial structure 124a and a first electrode 126q and a second electrode 128q disposed on the epitaxial structure 124a. In this embodiment, the epitaxial structure layer 124a is a semiconductor epitaxial structure layer. The first electrode 126q and the second electrode 128q are respectively disposed on the same side of the epitaxial structure layer 124a. Specifically, the light emitting unit 120j further includes a substrate 122a. The epitaxial structure layer 124a is disposed on the substrate 122a, and the first electrode 126q and the second electrode 128q are disposed on a side of the epitaxial structure layer 124a away from the substrate 122a. Then, an anisotropic conductive layer 150′ is attached to the circuit board 50a and the light emitting unit 120j. To be specific, the anisotropic conductive layer 150′ may be attached onto the circuit board 50a and cover positions of the electrode pads 52a where the first electrode 126q and the second electrode 128q are to be bonded. In some embodiments, the anisotropic conductive layer 150′ may also be attached to a side surface of the light emitting unit 52a close to the circuit board 50a. To be specific, the anisotropic conductive layer 150a may cover the first electrode 126q and the second electrode 128q. In this embodiment, the anisotropic conductive layer 150′ includes an insulating paste 152′ and a plurality of conductors 154′ dispersed in the insulating paste 152′.

Referring to FIGS. 19A and 19B, in this embodiment, the fabricating method of the light emitting device further includes aligning the first electrode 126q and the second electrode 128q to the electrode pads 52a. To be specific, the light emitting unit 120j is disposed on the anisotropic conductive layer 150a′, the first electrode 126q is aligned with one of the electrode pads 52a, and the second electrode 128q is aligned with another of the electrode pads 52a. Then, a process is performed on the anisotropic conductive layer 150′, such that the first electrode 126q and the second electrode 128q are electrically connected with the electrode pads 52a. In this embodiment, the process includes pressing or heating the parts of the anisotropic conductive layer 150a corresponding to the first electrode 126q and the second electrode 128q to form a processed anisotropic conductive layer 150″. To be specific, the parts of the processed anisotropic conductive layer 150″ corresponding to the first electrode 126q and the second electrode 128q are respectively electrically connected with the first electrode 126q and the second electrode 128q.

Referring to FIGS. 19C and 19D, in this embodiment, the fabricating method of the light emitting device further includes removing the substrate 122a after electrically connecting the first electrode 126q and the second electrode 128q with the electrode pads 52a, so as to form the light emitting device 200b. In this embodiment, a process of removing the substrate 122a includes performing a laser lift-off process and removing the substrate 122a by using a laser beam LL. In this embodiment, the light emitting diode epitaxial thin film may be directly bonded to the external circuit by adopting the fabricating method of the light emitting device. However, in some embodiments, the light emitting devices 100a, 100b, 100c, 100d, 100e, 100f, 100g, 100h, 100i, 100j, 100k, 100l, 100m, 100n, 100p, 100q, 100r, or light emitting diode packages in other forms may be bonded to the external circuit by adopting the fabricating method of the light emitting device of the embodiment. The invention does not intend to impose a limitation in this regard.

In this embodiment, the first electrode 126q and the second electrode 128q of the light emitting device 200b are bonded to the circuit board 50a through the anisotropic conductive layer 150″. In addition, the first electrode 126q and the second electrode 128q are electrically connected with the electrode pads 52a on the circuit board 50a through the anisotropic conductive layer 150″. Since the anisotropic conductive layer 150″, unlike the solder after being heated, may not become flowable after being pressed or heated, the light emitting device 200b does not easily have a short circuit or current leakage in the horizontal direction. In addition, the anisotropic conductive layer 150″ provides a more preferable buffering capability than a conventional solder. For example, in this embodiment, the substrate 122a is removed by using the laser beam LL after electrically connecting the first electrode 126q and the second electrode 128q with the electrode pads 52a. Specifically, the anisotropic conductive layer 150″ is slightly deformed during the process with laser beam LL and serves as a buffer for at least the epitaxial structure 124a, the first electrode 126q, and the second electrode 128q to prevent the buffered epitaxial structure 124a, the first electrode 126q, and the second electrode 128q from being damaged during the process. Accordingly, the yield rate of the light emitting device 200b may be increased.

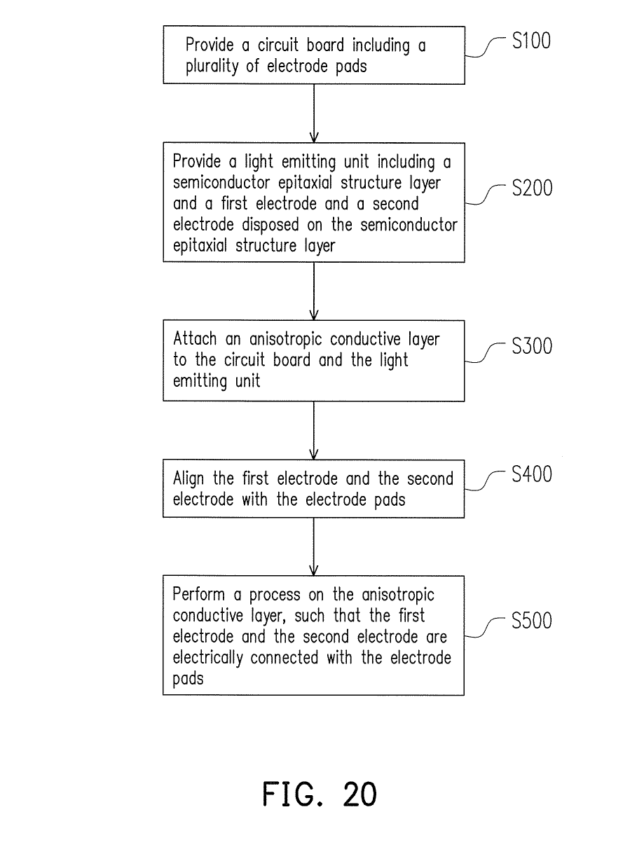

FIG. 20 is a flowchart illustrating a fabricating method of a light emitting device according to an embodiment of the invention. Referring to FIG. 20, the fabricating method of the light emitting device is at least applicable to, for example, the light emitting device 200a of FIG. 18C, the light emitting device 200b of FIGS. 19A to 19D, and the light emitting devices 100a, 100b, 100c, 100d, 100e, 100f, 100g, 100h, 100i, 100j, 100k, 100l, 100m, 100n, 100p, 100q, and 100r in FIGS. 1A to 17B. The fabricating method of the light emitting device includes steps as follows. At Step S100, the circuit board including the electrode pads are provided. Then, at Step S200, the light emitting unit is provided. The light emitting unit includes the semiconductor epitaxial structure layer and the first electrode and the second electrode disposed on the semiconductor epitaxial structure layer. Then, at Step S300, the anisotropic conductive layer is attached to the circuit board and the light emitting unit. At Step S400, the first electrode and the second electrode are aligned with the electrode pads. Subsequently, at Step S500, the process is performed on the anisotropic conductive layer, such that the first electrode and the second electrode are electrically connected with the electrode pads.

Besides, sufficient teaching, suggestions, and descriptions for implementation for the fabricating method of the light emitting device according to the embodiment of the invention may be obtained from the embodiments of FIGS. 1A to 18C. Thus, details in these respects will not be repeated in the following.

In view of the foregoing, the first electrode and the second electrode of the light emitting unit according to the embodiments of the invention extend outward from the semiconductor epitaxial structure layer to cover the encapsulant, namely, the light emitting device of the invention has a larger electrode area, so that when the light emitting device is to be assembled to an external circuit, the alignment accuracy of assembling is able to be effectively improved. Since the first electrode and the second electrode of the light emitting unit according to the embodiment of the invention extend upward from the semiconductor epitaxial structure layer, and protrude out of the encapsulant, it avails a follow-up chip bonding process. Moreover, the first electrode and the second electrode in the light emitting unit of the light emitting device according to the embodiments of the invention are electrically connected to the electrode pads through the anisotropic conductive layer. Thus, the light emitting device does not easily have a short circuit or current leakage in the horizontal direction, and the light emitting device has a preferable yield rate. Moreover, the fabricating method of the light emitting device according to the embodiments of the invention includes attaching the anisotropic conductive layer to the circuit board and the light emitting unit and performing a process to the anisotropic conductive layer, such that the first electrode and the second electrode are electrically connected with the electrode pads. Thus, with the fabricating method of the light emitting device, the light emitting device manufactured accordingly does not easily have a short circuit or current leakage in the horizontal direction and consequently has a preferable yield rate.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A light emitting device, comprising:
a circuit board, comprising a plurality of electrode pads;
a light emitting unit, comprising a semiconductor epitaxial structure layer, a first electrode, and a second electrode, wherein the first electrode and the second electrode are respectively disposed on the same side of the semiconductor epitaxial structure layer; and
an anisotropic conductive layer, wherein the first electrode and the second electrode are electrically connected with the electrode pads through the anisotropic conductive layer.

2. The light emitting device as claimed in claim 1, wherein the light emitting unit further comprises a substrate, the semiconductor epitaxial structure layer is disposed on the substrate, and the first electrode and the second electrode are disposed on a side of the semiconductor epitaxial structure layer away from the substrate.

3. The light emitting device as claimed in claim 1, further comprising a light transmissive layer, wherein the light emitting unit is disposed on the light transmissive layer, the light emitting unit is disposed between the light transmissive layer and the first electrode and between the light transmissive layer and the second electrode.

4. The light emitting device as claimed in claim 1, further comprising an encapsulant, encapsulating the light emitting unit and at least exposing a part of the first electrode and a part of the second electrode.

5. The light emitting device as claimed in claim 1, wherein the anisotropic conductive layer comprises an insulating paste and a plurality of conductors distributed in the insulating paste.

6. A fabricating method of a light emitting device, comprising:
providing a circuit board comprising a plurality of electrode pads;
providing a light emitting unit, wherein the light emitting unit comprises a semiconductor epitaxial structure layer and a first electrode and a second electrode disposed on the semiconductor epitaxial structure layer;
attaching an anisotropic conductive layer to the circuit board or the light emitting unit;
aligning the first electrode and the second electrode to the electrode pads; and
performing a process on the anisotropic conductive layer, such that the first electrode and the second electrode are electrically connected with the electrode pads.

7. The fabricating method of the light emitting device as claimed in claim 6, wherein the process comprises pressing parts of the anisotropic conductive layer corresponding to the first electrode and the second electrode, such that the parts of the anisotropic conductive layer corresponding to the first electrode and the second electrode are respectively electrically connected with the first electrode and the second electrode.

8. The fabricating method of the light emitting device as claimed in claim 6, wherein the process comprises heating parts of the anisotropic conductive layer corresponding to the first electrode and the second electrode, such that the parts of the anisotropic conductive layer corresponding to the first electrode and the second electrode are respectively electrically connected with the first electrode and the second electrode.

9. The fabricating method of the light emitting device as claimed in claim 6, wherein the light emitting unit further comprises a substrate, the semiconductor epitaxial structure layer is disposed on the substrate, and the fabricating method of the light emitting device further comprises removing the substrate after electrically connecting the first electrode and the second electrode with the electrode pads.

10. The fabricating method of the light emitting device as claimed in claim 9, wherein a process of removing the substrate comprises removing the substrate by performing a laser lift-off process.

11. The fabricating method of the light emitting device as claimed in claim 6, wherein the anisotropic conductive layer comprises an insulating paste and a plurality of conductors distributed in the insulating paste.

12. A light emitting device, comprising:
a circuit board;
a light emitting unit, comprising:
a substrate;
a semiconductor epitaxial structure layer, disposed on the substrate; and
a first electrode and a second electrode, respectively disposed on the same side of the semiconductor epitaxial structure layer;
a light transmissive layer, wherein the light emitting unit is disposed on the light transmissive layer;
an encapsulant, located between the light transmissive layer and the light emitting unit, encapsulating the light emitting unit, and exposing at least a part of the first electrode and a part of the second electrode, wherein the first electrode and the second electrode respectively extend outward from the semiconductor epitaxial structure layer and respectively cover a part of an upper surface of the encapsulant; and
an anisotropic conductive layer, wherein the first electrode and the second electrode are electrically connected with the circuit board through the anisotropic conductive layer.

13. The light emitting device as claimed in claim 12, wherein the anisotropic conductive layer comprises an insulating paste and a plurality of conductors distributed in the insulating paste.

14. The light emitting device as claimed in claim 12, wherein the first electrode comprises a first electrode portion connected to the semiconductor epitaxial structure layer and a first electrode extending portion connected to the first electrode portion, and the second electrode comprises a second electrode portion connected to the semiconductor epitaxial structure layer and a second electrode extending portion connected to the second electrode portion, and the first electrode extending portion and the second electrode extending portion respectively extend outward to at least a part of the upper surface of the encapsulant.

15. The light emitting device as claimed in claim 14, wherein the first electrode extending portion and the second electrode extending portion are aligned with or retracted from an edge of the upper surface of the encapsulant.

16. The light emitting device as claimed in claim 14, wherein the first electrode extending portion comprises a plurality of first grating type electrodes, and the second electrode extending portion comprises a plurality of second grating type electrodes, the first grating type electrodes are distributed on the first electrode portion and a part of the upper surface of the encapsulant, and the second grating type electrodes are distributed on the second electrode portion and a part of the upper surface of the encapsulant.

17. The light emitting device as claimed in claim 14, wherein the first electrode extending portion comprises a plurality of first grating type electrodes, and the second electrode extending portion comprises a plurality of second grating type electrodes, the first grating type electrodes are distributed on the first electrode portion and a part of the upper surface of the encapsulant, and the second grating type electrodes are distributed on the second electrode portion and a part of the upper surface of the encapsulant.
